(19) United States
(12) Patent Application Publication
(10) Pub. No.: US 2026/0314389 A1
(43) Pub. Date: Oct. 8, 2026

(54) CAPACITOR CELL REGIONS, SEMICONDUCTOR DEVICE INCLUDING SAME AND METHODS OF MANUFACTURING SAME

(71) Applicant: TAIWAN SEMICONDUCTOR MANUFACTURING COMPANY, LTD., Hsinchu (TW)

(72) Inventor: Mei-Chen CHUANG, Hsinchu (TW)

(21) Appl. No.: 19/285,398

(22) Filed: Jul. 30, 2025

Related U.S. Application Data
(60) Provisional application No. 63/783,040, filed on Apr. 3, 2025.

(51) Int. Cl. H01L 23/522; H01L 21/768; H01L 23/528; H10D 1/00

(52) U.S. Cl. CPC H10W 20/496; H10D 1/041; H10W 20/031; H10W 20/43

(57) ABSTRACT

A semiconductor device includes: in a first metallization (M_1st) layer, M_1st segments having a first pitch and substantially having a first width a uniform first gap therebetween; and capacitor cell regions (cap cells) arranged in an array and including first cap cells and second cap cells; each cap cell having a first quantity, and a substantially uniform physical arrangement, of the M_1st segments; electrical arrangements of the M_1st segments being different for the second cap cells than for the first cap cells; for each of the cap cells, couplings between the M_1st segments and correspondingly a first voltage or a second voltage being arranged such that: each of the first cap cells providing substantially a first capacitance; and each of the second cap cells providing substantially a non-zero second capacitance smaller than the first capacitance.

### PRIORITY CLAIM

The application claims the priority of U.S. Provisional Application No. 63/783,040, filed Apr. 3, 2025, which is incorporated herein by reference in its entirety.

### BACKGROUND

The semiconductor integrated circuit (IC) industry produces a wide variety of analog and digital devices to address issues in a number of different areas. Developments in semiconductor process technology nodes have progressively reduced component sizes and tightened spacing resulting in progressively increased transistor density. ICs have become smaller.

### BRIEF DESCRIPTION OF THE DRAWINGS

One or more embodiments are illustrated by way of example, and not by limitation, in the figures of the accompanying drawings, wherein elements having the same reference numeral designations represent like elements throughout. The drawings are not to scale, unless otherwise disclosed.

FIGS. 1A-1C are corresponding block diagrams, in accordance with some embodiments.

FIG. 2 is a block diagram of an array, in accordance with some embodiments.

FIGS. 3A-3H are corresponding layout diagrams, in accordance with some embodiments.

FIGS. 4A-4B are corresponding cross-sectional diagrams, in accordance with some embodiments.

FIGS. 5A-5D and 5E(1)-5E(2) are corresponding tables, in accordance with some embodiments.

FIGS. 6 and 7A-7C are corresponding flowcharts of corresponding methods, in accordance with some embodiments.

FIG. 8 is a block diagram of an electronic design automation (EDA) system in accordance with some embodiments.

FIG. 9 is a block diagram of an integrated circuit (IC) manufacturing system, and an IC manufacturing flow associated therewith, in accordance with some embodiments.

### DETAILED DESCRIPTION

The following disclosure discloses many different embodiments, or examples, for implementing different features of the subject matter. Examples of components, materials, values, steps, operations, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows include embodiments in which the first and second features are formed in direct contact, and further include embodiments in which additional features are formed between the first and second features, such that the first and second features are in indirect contact. In addition, the present disclosure repeats reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, are used herein for ease of description to describe one element's or feature's relationship to another element(s) or feature(s) as illustrated in the figures. The spatially relative terms are intended to encompass different orientations of the device in use or operation in addition to the orientation depicted in the figures. The apparatus is otherwise oriented (rotated 90 degrees or at other orientations) and the spatially relative descriptors used herein are likewise interpreted accordingly. In some embodiments, the term standard cell structure refers to a standardized building block included in a library of various standard cell structures. In some embodiments, various standard cell structures are selected from a library thereof and are used as components in a layout diagram representing a circuit.

In some embodiments, a semiconductor device includes: in a first metallization (M_1st) layer, M_1st segments extending in a first direction and having a first pitch, wherein, relative to a second direction perpendicular the first direction, each of the M_1st segments substantially having a first width and a substantially uniform first gap therebetween; and capacitor cell regions (cap cells) arranged in an array and including one or more first cap cells and one or more second cap cells, wherein each cap cell having a first quantity, and a substantially uniform physical arrangement, of corresponding ones of the M_1st segments; and wherein, for each of the cap cells, couplings between the M_1st segments and correspondingly a first voltage or a second voltage being arranged such that: each of the first cap cells providing substantially a first capacitance; and each of the second cap cells providing substantially a non-zero second capacitance smaller than the first capacitance; and wherein electrical arrangements of the M_1st segments being different for the second cap cells than for the first cap cells. In some embodiments, a cap cell in a semiconductor device based on a layout diagram is referred to as a fabricated cap cell. In some embodiments, where segments of a pair of adjacent ones of M_1st segments are coupled correspondingly to V_Net_A and V_Net_B, the pair is referred to as an M_1st capacitive pair (CPR). In some embodiments, where both segments of the pair are coupled to V_Net_A or both segments of the pair are coupled to V_Net_B, the pair is referred to as an M_1st dummy pair.

According to another approach in which each cap cell can have up to a maximum of N quantity of M_1st segments for the M_1st layer, the cap cells have correspondingly different physical arrangements of the conductive segments for purposes of achieving different cell capacitances. That is, according to the other approach, the cap cells have substantially non-uniform physical arrangements. The non-uniformity of the cap cells according to the other approach is worsened/exaggerated in the corresponding fabricated cap cells due to (A) non-uniform corrections introduced by resolution enhancement techniques (RETs) and/or optical proximity correction (OPC) and (B) manufacturing tolerances, where the effects of (A) and/or (B) result in worsened/exaggerated capacitor mismatch. Capacitor mismatch reduces reliability and/or reduces performance and/or increases power consumption and/or the like of the fabricated cap cells. By contrast, at least some of the present embodiments produce an array of cap cells comprised of uniform M_1st-segment-count cap cells, where the uniformity lessens the variations in fabricated cap cells introduced by (i) RETs and/OPC and (ii) manufacturing tolerances as compared to the other approach, i.e., where the uniformity reduces mismatch between the fabricated cap cells as compared to the other approach. The array of uniform M_1st-segment-count cap cells according to at least some of the present embodiments improve reliability and/or performance and/or power consumption and/or the like of the fabricated cap cells as compared to the other approach.

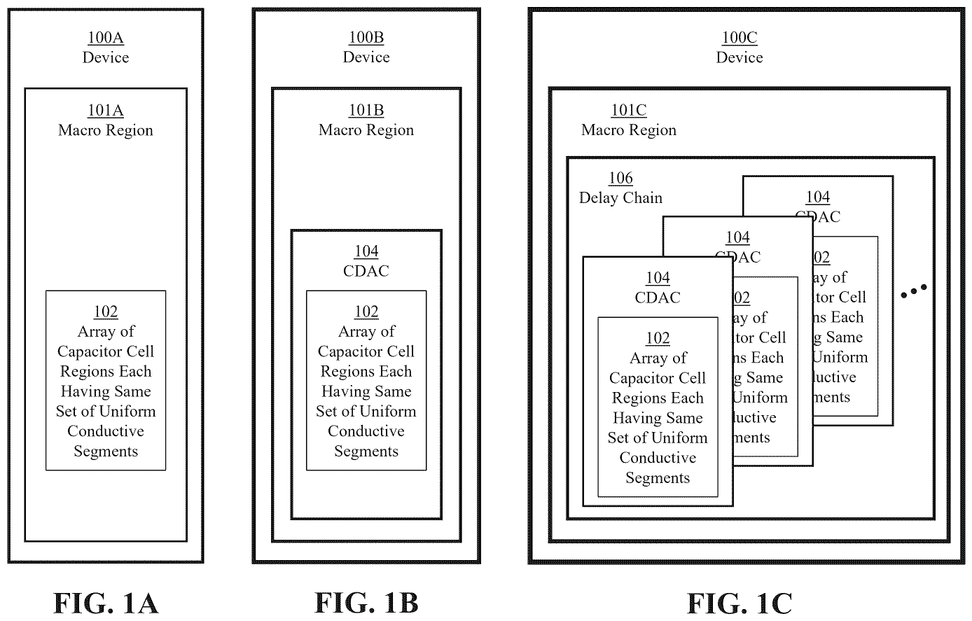

FIGS. 1A-1C are block diagrams of corresponding devices 100A, 100B and 100C, in accordance with some embodiments.

Each of devices 100A-100C is an example of an integrated circuit (IC). In some embodiments, each of devices 100A-100C is referred to as a semiconductor device. Devices 100A, 100B and 100C correspondingly include macro regions 101A, 101B and 101C.

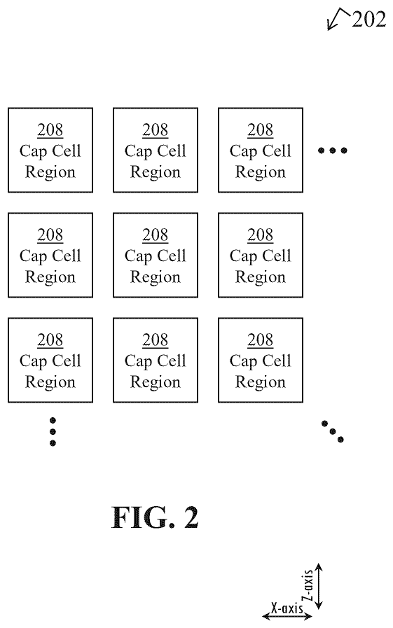

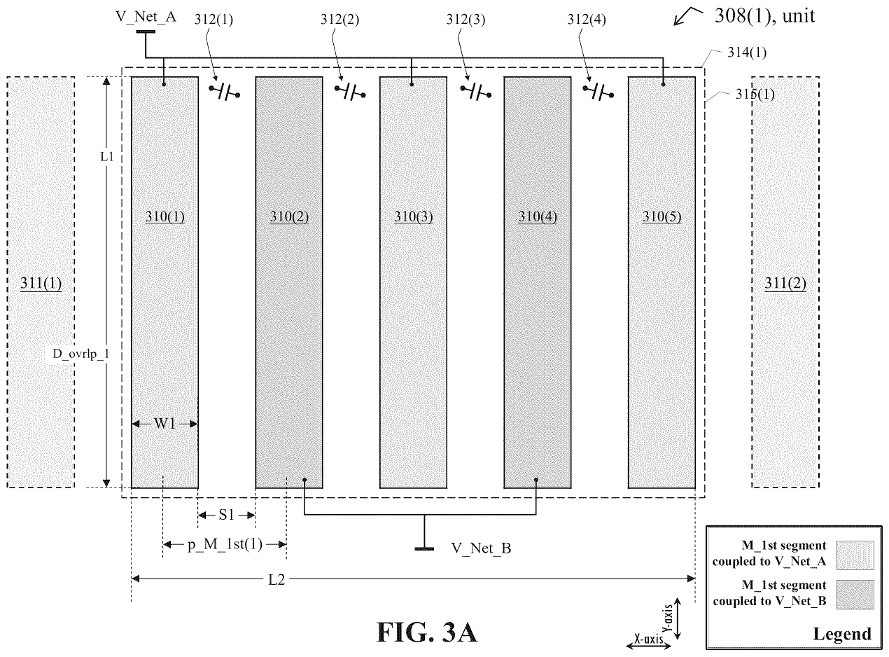

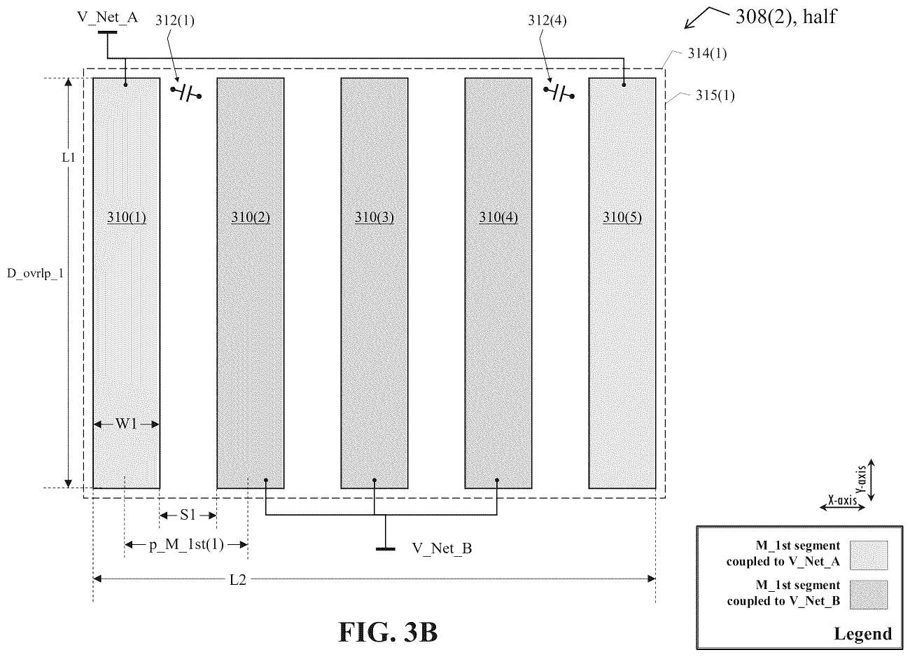

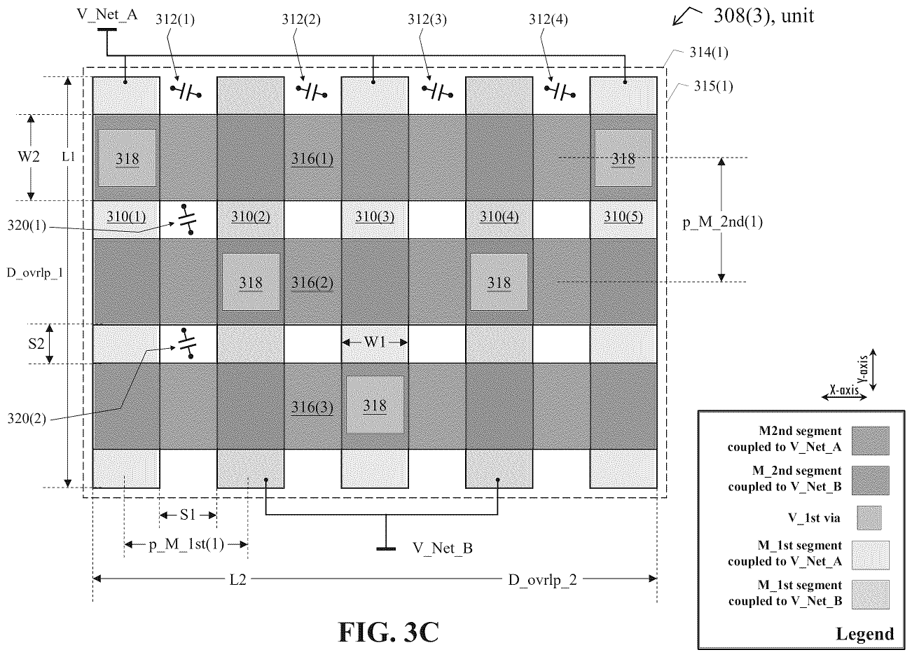

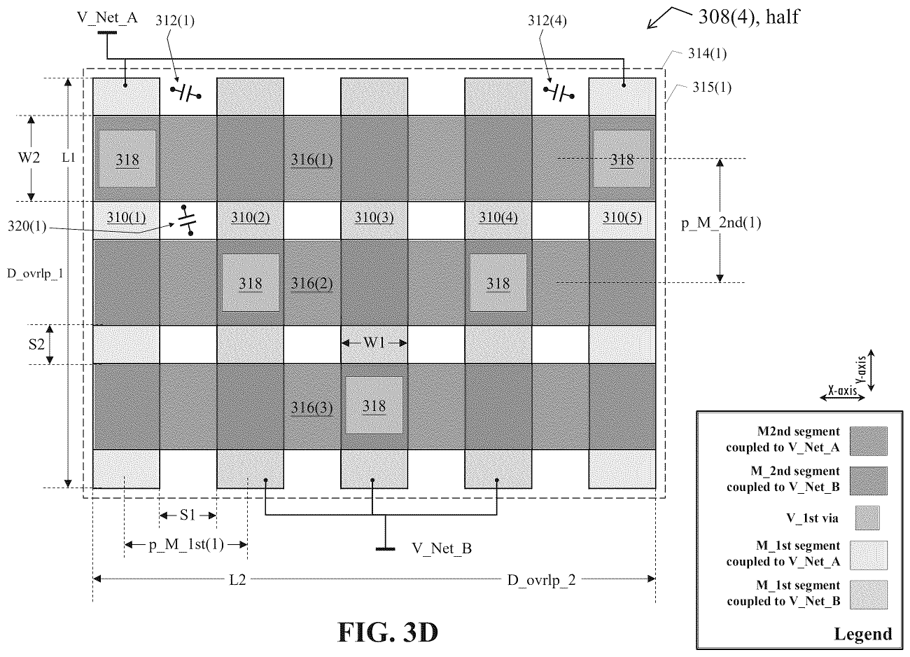

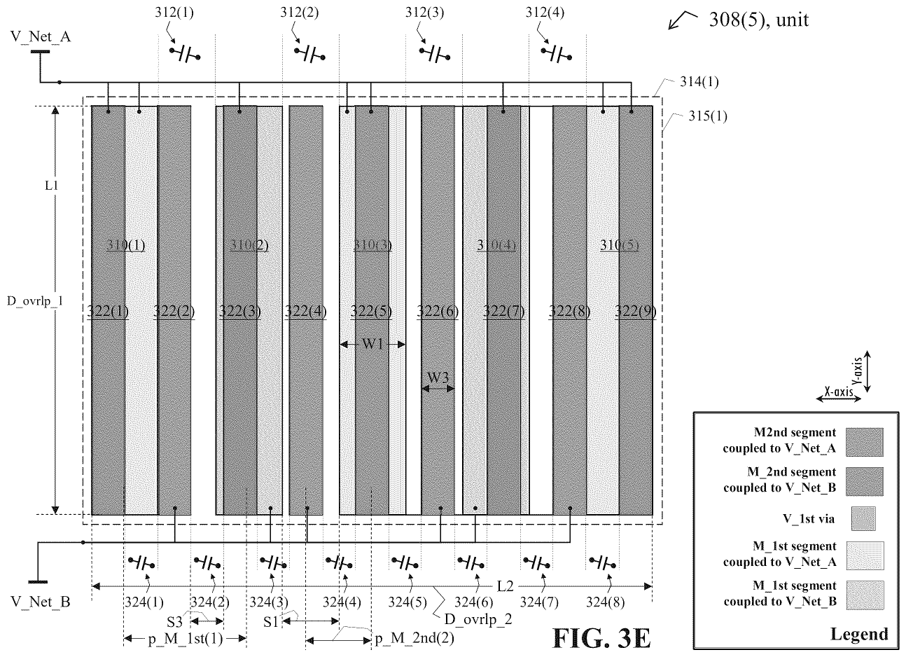

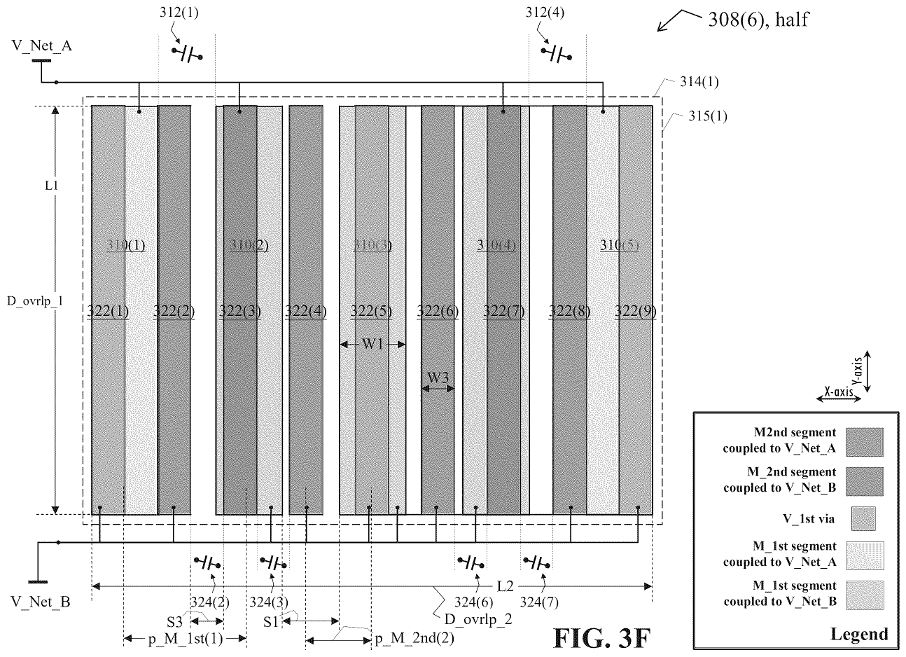

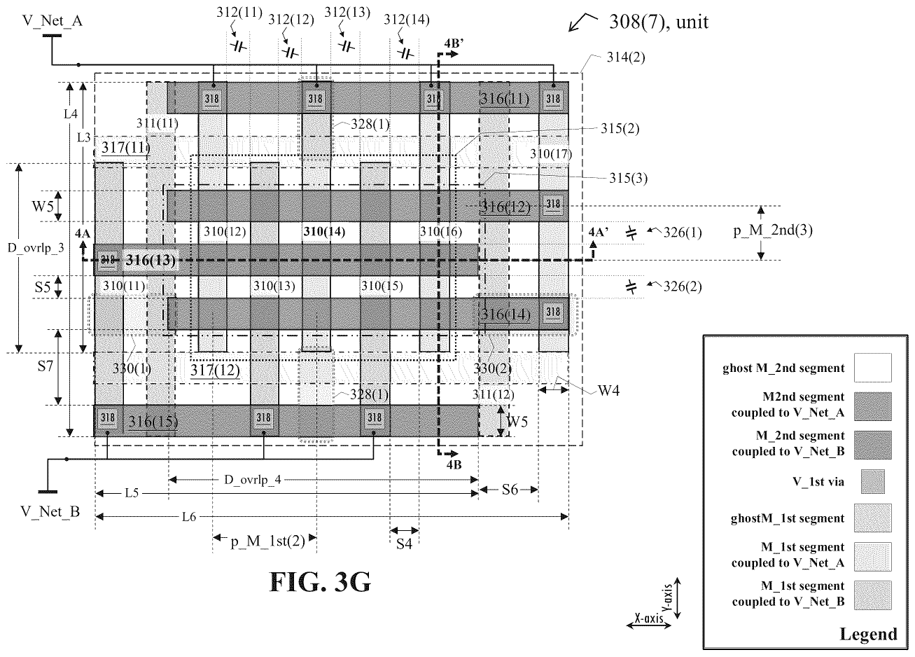

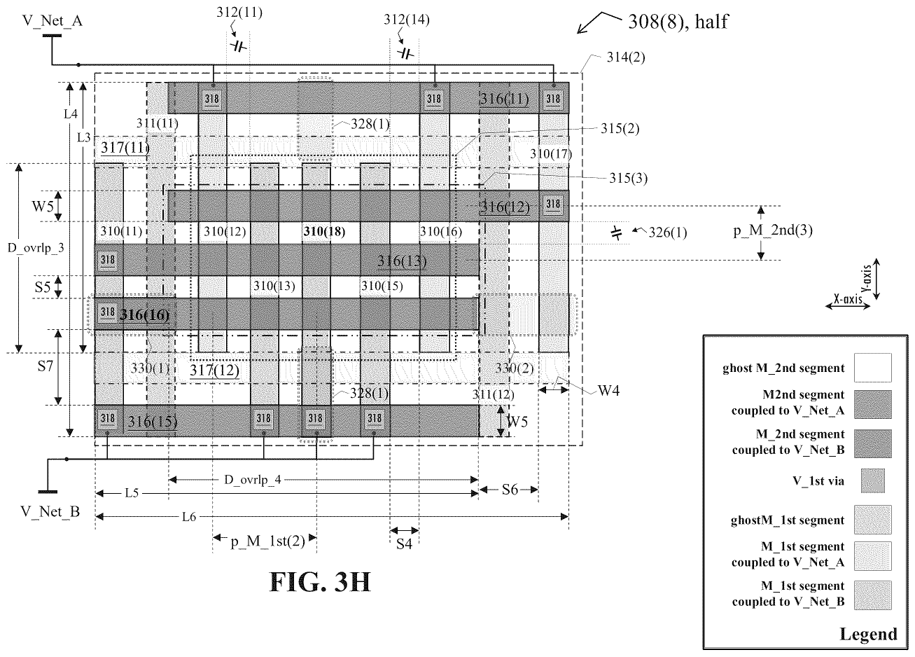

In FIG. 1A, macro region 101A includes an array 102 (see FIG. 2) of capacitor cell regions (cap cells) (see FIGS. 3A-3H), where each cap cell has a substantially same set of substantially uniform conductive segments which are configurable as plates of corresponding capacitors. In FIG. 1B, macro region 101B includes a capacitor digital-to-analog converter (CDAC) 104, where CDAC 104 includes cap cell array 102.

In FIG. 1C, macro region 102C includes a delay chain 106. In some embodiments, delay chain 106 is referred to as a delay line. Delay chain 106 includes multiple instances of CDAC 104. In some embodiments, delay chain 106 includes delay stages (not shown) that are coupled in series, each delay stage including a driver device (not shown) coupled between an input node and an output node of the delay stage, and a corresponding instance of CDAC 104, where each instance of CDAC 104 includes a corresponding instance of cap cell array 102

In some embodiments, each of macro regions 101A-101C includes one or more active devices, passive devices, or the like. Examples of active devices or active elements include, but are not limited to, transistors, diodes, or the like. Examples of passive elements include, but are not limited to, capacitors, inductors, fuses, resistors, or the like.

In some embodiments, macro region 101A is comprised, and each of macro regions 101B and 101C is further comprised correspondingly, of one or more instances of a functional cell region (not shown). In such embodiments, macro region 101A is configured to provide/execute a given computational function which is comprised of less complicated functions provided correspondingly by the one or more instances of the functional cell region. In some embodiments, one or more instances of the functional cell region represent intercoupled building blocks which comprise macro region 101A.

In some embodiments, each of macro regions 101A-101C is understood in the context of an analogy to the architectural hierarchy of modular programming, in which subroutines/procedures are called by a main program (or by other subroutines) to carry out a given computational function. In this context, devices 100A-100C correspondingly use macro regions 101A-101 to perform one or more given functions. Accordingly, in this context and in terms of architectural hierarchy, each of devices 100A-100C is analogous to the main program and each of macro regions 101A-101C is analogous to subroutines/procedures. In some embodiments, each of macro regions 101A-101C is a soft macro. In some embodiments, each of macro regions 101A-101C is a hard macro. In some embodiments, each of macro regions 101A-101C is a soft macro which is described digitally in register-transfer level (RTL) code. In some embodiments, synthesis, placement, and routing have yet to have been performed on each of macro regions 101A-101C such that the corresponding soft macro can be synthesized, placed, and routed for a variety of process technology nodes. In some embodiments, each of macro regions 101A-101C is a hard macro which is described digitally in a binary file format (e.g., Graphic Database System II (GDSII) stream format), where the binary file format represents planar geometric shapes, text labels, other information, and the like of one or more layouts correspondingly of each of macro regions 101A-101C in hierarchical form. In some embodiments, a binary file format is referred to as a non-text file format. In some embodiments, synthesis, placement, and routing have been performed on macro region 101 such that the hard macro is specific to a particular process technology node.

In some embodiments, examples of functions provided by a macro region (e.g., macro region 101A, 101B and/or 101C) include a memory, a power grid, a clock tree, an adder, a phase-locked loop (PLL), a delay-locked loop (DLL), a flip-flop, a shift register, an analog-to-digital converter (ADC), a digital-to-analog converter (DAC), interfaces, higher-level Boolean logic, or the like. Example memories include a static random access memory (SRAM), a dynamic RAM (DRAM), a resistive RAM, a magnetoresistive RAM (MRAM), a read only memory (ROM), or the like. An example of a flip-flop is a scan-insertion type of D flip-flop (SDFQ), or the like. In some embodiments, examples of functions provided by functional cell regions include an inverter, a tri-state inverter, a buffer, a latch a multiplexer (MUX), a driver, a latch, delay, a half adder, a full adder, a compressor, lower-level Boolean logic, or the like, Examples of lower-level Boolean logic include AND, OR, NAND, NOR, XOR, INV, AND-OR-Invert (AOI), OR-AND-Invert (OAI), or the like.,

Each of macro regions 101A-101C includes corresponding segments in one or more metallization layers. Figures of the present disclosure assume a Cartesian coordinate system (unless noted otherwise) in which first, second and third directions are, e.g., correspondingly parallel to the X-axis, the Y-axis and the Z-axis. In some embodiments, the first to third directions correspond to directions other than the X-axis, Y-axis and Z-axis. In some embodiments, long and short axes of the segments extend correspondingly in the first and second directions in even ones of the metallization layers; in such embodiments, long and short axes of the segments extend correspondingly in the second and first directions in odd ones of the metallization layers. In some embodiments, boundaries of cell regions are described in terms of the first and second directions.

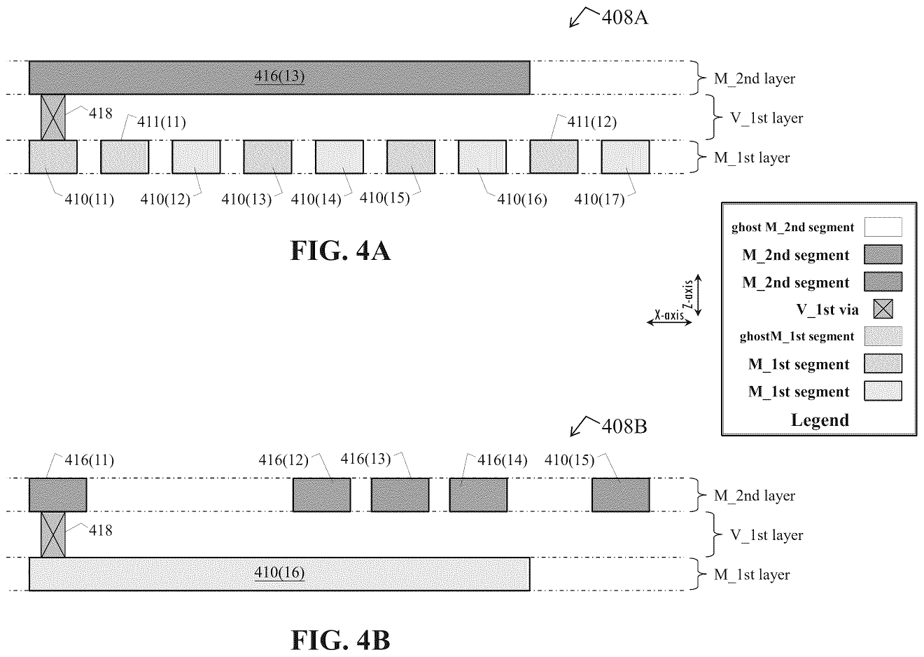

In some embodiments, each of macro regions 101A-101C includes one or more portions corresponding to a transistor-components layer (not sown) having circuitry components, e.g., transistors, formed thereon in a front-end-of-line (FEOL) fabrication. Correspondingly in each of macro regions 101A-101C, above and/or below an active region (AR) layer (not shown), various metal layers (see FIGS. 4A-4B) are interleaved with one or more corresponding interconnection layers (see FIGS. 4A-4B) in a stacked architecture over and/or under the AR layer in a back end of line (BEOL) fabrication. The BEOL fabrication provides a power network and/or routing for circuitry of devices 100A-100C, and macro regions 101A-101C correspondingly included therein.

FIG. 2 is a block diagram of an array 202, in accordance with some embodiments.

Array 202 is an array of capacitor cell regions (cap cells) 208. Cap cell array 202 is an example of cap cell array 102 of FIGS. 1A-1C, or the like.

Each instance of cap cell 208 includes the same number of one or more metallization layers. On a layer-specific basis, each cap cell 208 has a substantially same set of physically substantially uniform conductive segments, where each set has a substantially uniform physical arrangement of the conductive. Each of the conductive segments is selectively configured to be coupled to a first reference voltage or a second reference voltage, where the first and second reference voltages are different. Where the conductive segments of a pair of adjacent conduct segments are coupled correspondingly to the first reference voltage and the second reference voltage, a capacitance is induced between the conductive segments of the pair. In each instance of cap cell 208, and for a given metallization layer therein, whereas the physical arrangement of the set of conductive segments is substantially unform, the electrical arrangement of the set of conductive segments is not necessarily uniform. Rather, to adjust the overall capacitance of array 202, in some embodiments, one or more instances of cap cell 208 have a different cell capacitance.

For example, consider an instance of array 202 in which all but one instance of cap cell 208 are first cap cells configured for a maximum cell capacitance and a single instance of cap cell 208 is a second cap cell configured for less than the maximum cell capacitance (e.g., half the maximum cell capacitance). Continuing the example, for a given metallization layer, the electrical arrangement of the set of conductive segments in the second cap cell (e.g., 308(2) of FIGS. 3B, 308(4) of FIGS. 3D, 308(6) of FIGS. 3F and 308(8) of FIG. 3H) has a different electrical arrangement of the set of conductive segments as compared to the electrical arrangement of the set of conductive segments in each of the first cap cells (e.g., 308(1) of FIGS. 3A, 308(3) of FIGS. 3C, 308(5) of FIGS. 3E and 308(7) of FIG. 3G).

FIGS. 3A-3H are layout diagrams of corresponding cap cells 308(1)-308(8), in accordance with some embodiments.

In some embodiments, the cap cell regions of FIGS. 3A-3H are a type of capacitor referred to as a metal-oxide-metal (MOM) capacitor. In some embodiments, the cap cell regions of FIGS. 3A-3H are a type of capacitor other than a MOM capacitor. In some embodiments, the maximum capacitance, kp _1, of a first fabricated cap cell region based on maximum-capacitance-versions of cap cell regions disclosed herein (e.g., 308(1), 308(3), 308(5) and 308(7)) is a range of about one femtofarad (1 fF) such that (1*10\hat{ }\hat{ }(0.15))≤kp_1<(1*10\hat{ }\hat{ }(−14)). In some embodiments, the maximum capacitance, kp _2, of a second fabricated cap cell region based on maximum-capacitance-versions of cap cell regions disclosed herein (e.g., 308(1), 308(3), 308(5) and 308(7)) is in a second range of about one-tenth femtofarad (0.1 fF) such that (1*10\hat{ }\hat{ }(₋16))≤kp_2<(1*10\hat{ }\hat{ }(−15)). In some embodiments, the maximum capacitance, kp_3, of a fabricated cap cell region based on maximum-capacitance-versions of cap cell regions disclosed herein (e.g., 308(1), 308(3), 308(5) and 308(7)) is a third range greater than 1 fF such that (1*10\hat{ }\hat{ }(₋15))<kp_3. In some embodiments, the maximum capacitance, kp_4, of a fabricated cap cell region based on maximum-capacitance-versions of cap cell regions disclosed herein (e.g., 308(1), 308(3), 308(5) and 308(7)) is a fourth range less than 0.1 fF such that kp_4<(1*10\hat{ }\hat{ }(₋16)).

In a layout diagram, structures in a corresponding semiconductor device are represented by patterns (also known as shapes). For simplicity of discussion, elements in the layout diagrams of FIGS. 3A-3H will be referred to as if they are structures rather than patterns. For example, shapes in FIG. 1A representing instances of a via structure (via) are referred to as vias per se rather than as via shapes.

A layout diagram is a top view. Shapes in the layout diagram are two-dimensional relative to, e.g., the X-axis and the Y-axis, whereas the device being represented is three-dimensional. As such, a shape in such layout diagrams is described as having a width/length relative to the X-axis and a height relative to the Y-axis. Relative to the Z-axis, e.g., a bottom/back side of a first component being represented in the layout diagram is stacked on a top/front side of a second component device being represented in the layout diagram, or a top/front back side of the first component is stacked, e.g., under a bottom/back side of the second component.

In general, a layout diagram assumes a Cartesian coordinate system in which dimensions parallel to the X-axis or Y-axis are shown. Typically, relative to the Z-axis, a semiconductor device is organized as a stack of layers in which are located corresponding structures, i.e., to which belong corresponding structures. Each shape in the layout diagram represents, more particularly, a component in a corresponding layer of the corresponding device. Also, typically, the layout diagram represents relative depth, i.e., positions along the Z-axis, of shapes and corresponding layers by superimposing a second shape on a first shape so that the second shape at least partially overlaps the first shape. For simplicity of illustration, some structures which have a first order of stacking along the Z-axis in the device are represented in the layout diagram using a second order of stacking along the Z-axis, i.e., a different/distorted stacking order.

Layout diagrams vary in terms of the amount of detail represented. In some circumstances, selected layers of a layout diagram are combined/abstracted into a single layer, e.g., for purposes of simplification. Alternatively, and/or additionally, in some circumstances, not all layers of the corresponding device are represented, i.e., selected layers of the layout diagram are omitted, e.g., for simplicity of illustration. Alternatively, and/or additionally, in some circumstances, not all elements of a given depicted layer of the corresponding device are represented, i.e., selected elements of the given depicted layer of the layout diagram are omitted, e.g., for simplicity of illustration. The layout diagrams disclosed herein are examples of layout diagrams in which selected layers and/or selected elements of depicted given layers, have been omitted.

Depending upon the numbering convention of the corresponding process technology node by which a device is to be fabricated, on a front side of the device, an initial layer of metallization, i.e., a layer metallization closest to the active region (AR) layer, is either metallization layer zero (MET0) or metallization layer one (MET1), and correspondingly an initial interconnection layer, i.e., a closest interconnection layer on the initial metallization layer, is either interconnection layer zero (VIA0) or interconnection layer one (VIA1). In such embodiments, again depending upon the numbering convention of the corresponding process technology node, on a back side (not shown) of the device, an initial buried metallization layer, i.e., the buried metallization layer closest to the AR layer, is either buried metallization layer zero (BMET0) or buried metallization layer one (BMET1), and correspondingly an initial interconnection layer, i.e., a closest buried interconnection layer under the initial buried metallization layer, is either interconnection layer zero (VIA0) or interconnection layer one (VIA1).

In general regarding the figures disclosed herein (unless noted otherwise), the following nomenclature is adopted regarding the front side of a device: the initial metallization layer is assumed to be MET0; the initial interconnection layer is assumed to be VIA0; the first next metallization layer is assumed to be MET1; the next interconnection layer is assumed to be VIA1; and the second next metallization layer is assumed to MET2. Metallization segments in layer MET0 are referred to as M0 segments. Via structures in layer VIA0 are referred to as V0 structures. Metallization segments in layer MET1 are referred to as M1 segments. Via structures in layer VIA1 are referred to as V1 structures. Metallization segments in layer MET2 are referred to as M2 segments. In some embodiments, in a given metallization layer, widths of the segments in the given metallization layer have a uniform width, where width is defined along a short axis of the segment. In some embodiments, segment width increases with metallization layer number, i.e., a segment in layer MET1 is wider than a segment in layer MET0, a segment in MET2 is wider than a segment in layer MET1, or the like.

In general, regarding the figures disclosed herein (unless noted otherwise), or the like, the following nomenclature is adopted regarding the back side of a device: the initial buried metallization layer is assumed to be BMET0; the initial buried interconnection layer is assumed to be BVIA0; the first next buried metallization layer is assumed to be BMET1; the next buried interconnection layer is assumed to be BVIA1; and the second next buried metallization layer is assumed to BMET2. Metallization segments in layer BMET0 are referred to as buried M0 (BM0) segments. Via structures in layer BVIA0 are referred to as BV0 structures. Metallization segments in layer BMET1 are referred to as buried M1 (BM1) segments. Via structures in layer BVIA1 are referred to as BV1 structures. Metallization segments in layer BMET2 are referred to as buried M2 (BM2) segments. In some embodiments, in a given buried metallization layer, widths of the segments in the given buried metallization layer have a uniform width. In some embodiments, segment width increases with metallization layer number, i.e., a segment in layer BMET1 is wider than a segment in layer BMET0, a segment in BMET2 is wider than a segment in layer BMET1, or the like.

More specifically, FIGS. 3A-3B are layout diagrams of corresponding cap cells 308(1)-308(2), in accordance with some embodiments.

In FIG. 3A, cap cell region (cap cell) 308(1) is an example of one or more of cap cells 208 of FIG. 2. In FIG. 3B, cap cell 308(2) is an example of one or more of cap cells 208 of FIG. 2.

In FIGS. 3A-3B, in a first metallization (M_1st) layer, each of cap cells 308(1) and 308(2) includes M_1st segments 310(1)-310(5) extending in a first direction (e.g., parallel to the Y-axis) and having a pitch p_M_1st(1). In some embodiments, the M_1st layer is layer MET0, layer MET1, layer MET2, layer MET3 or layer MET4. In some embodiments, the M_1st layer is layer BMET0, layer BMET1, layer BMET2, layer BMET3 or layer BMET4. In some embodiments, the M_1st layer is a layer other than one of layers MET0-MET4 or BMET0-BMET4.

Relative to a second direction (e.g., parallel to the X-axis) perpendicular the first direction, each of M_1st segments 310(1)-310(5) has a uniform width, i.e., substantially has a first width W1. As a result of the pitch and uniform width, adjacent ones of M_1st segments 310(1)-310(5) are separated from each other by a unform distance, i.e., substantially by a distance S1.

More generally, cap cells 308(1) and 308(2) include N quantity of M_1st segments, where N is a positive integer and 3≤N, and where N is assumed to be N=5in FIGS. 3A-3B. In some embodiments, N is a positive integer equal to or greater than 3 but not equal to 5.

Relative to the Y-axis, each of M_1st segments 310(1)-310(5) has a length L1. Cap cell 308(1) has a cell boundary 314(1).

In each of cap cells 308(1) of FIGS. 3A and 308(2) of FIG. 3B, each of M_1st segments 310(1)-310(5) has an overlap section with respect to an adjacent corresponding one of the M_1st segments, each overlap section substantially having an overlap-length D_ovrlp_1 with respect to an adjacent corresponding one of M_1st segments 310(1)-310(5).

In FIGS. 3A-3B, in each of M_1st segments 310(1)-310(5), the overlap section spans substantially the entire M_1st segment such that the overlap-length is substantially the same (=≈) as the overall length, D_ovrlp_1=≈L1. In some embodiments, the overlap section spans a fraction of the length (e.g., FIGS. 3G-3H). Cap cell 308(1) has an overlap boundary 315(1). Because D_ovrlp_1=≈L1, overlap boundary 315(1) is the same as cell boundary 314(1).

During manufacture, e.g., during a BEOL fabrication, each of M_1st segments 310(1)-310(5) is selectively configured to be coupled to a first voltage V_Net_A or a second voltage V_Net_B, where V_Net_A is different than V_Net_B,, i.e., V_Net_A≠V_Net_B. In some embodiments, V_Net_A is VDD and V_Net_B is VSS. In some embodiments, V_Net_A and V_Net_B are voltages correspondingly other than VDD and VSS.

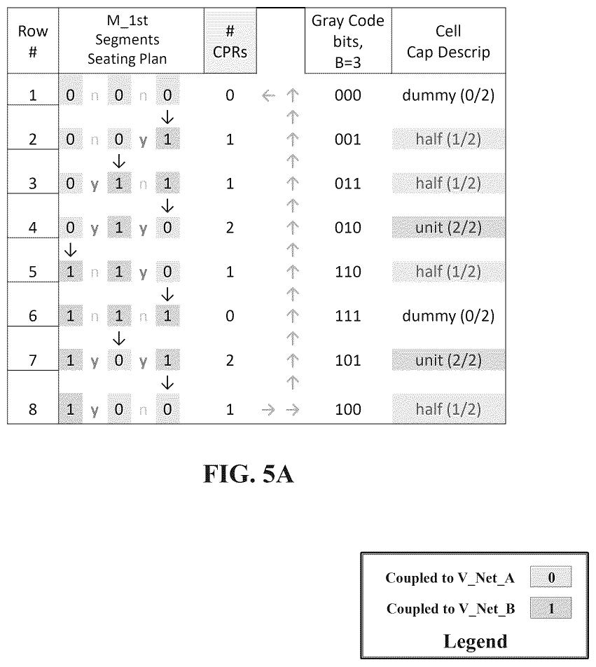

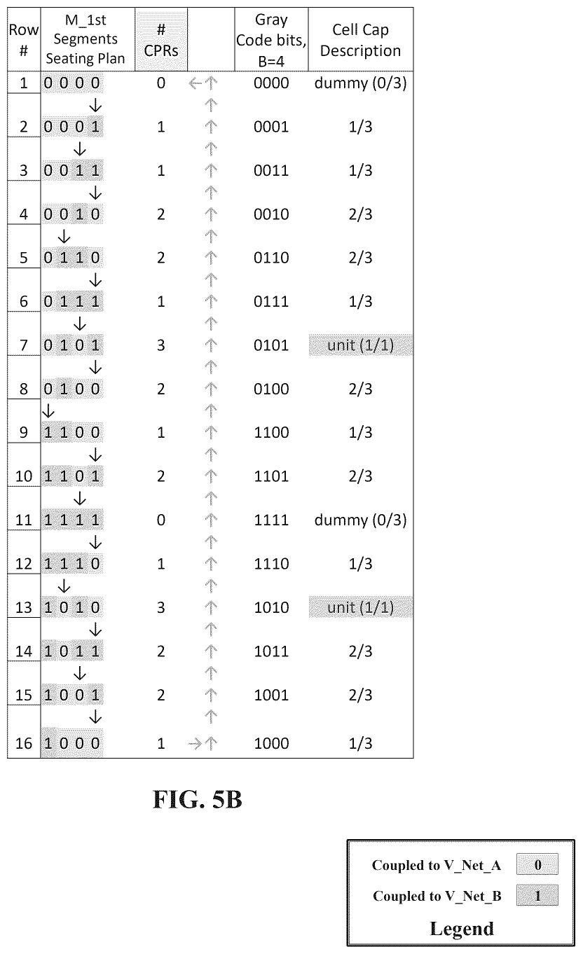

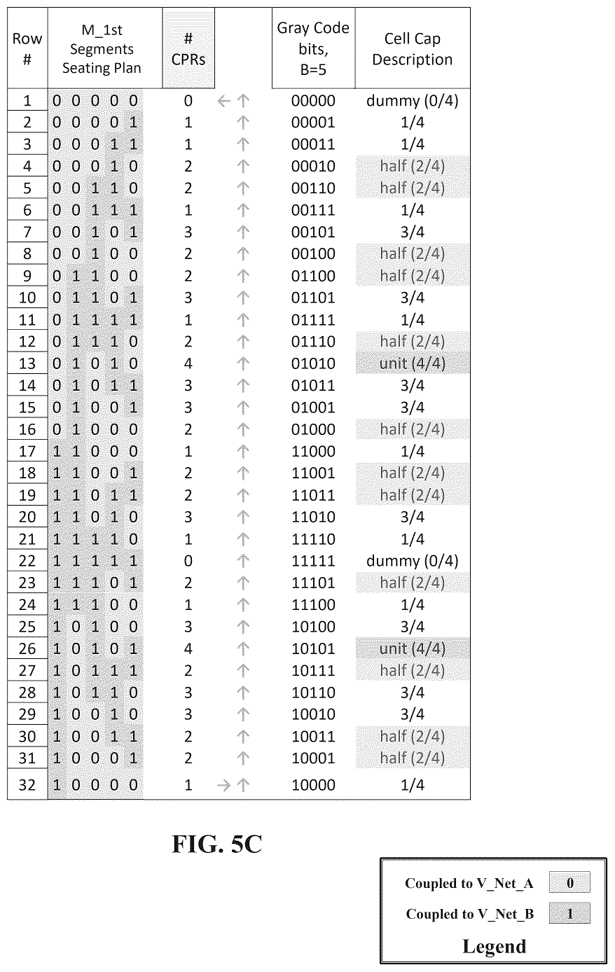

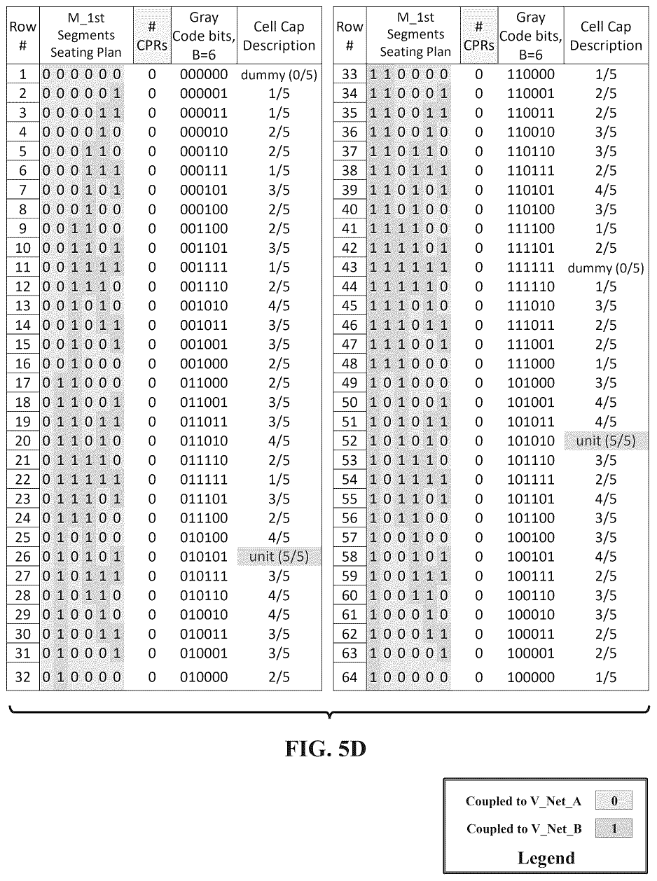

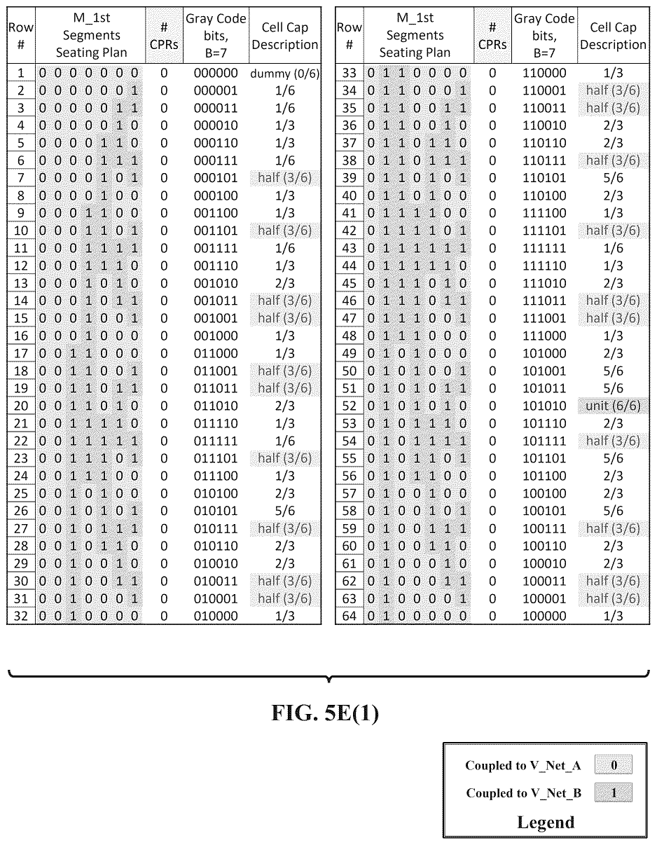

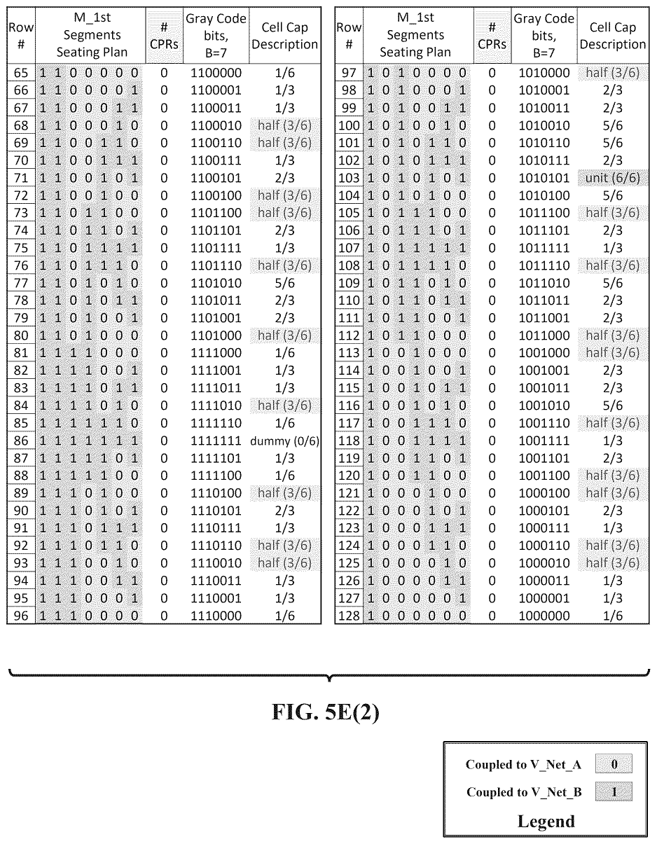

In some embodiments, an arrangement by which M_1st segments 310(1)-310(5) are coupled to V_Net_A or V_Net_B is referred to as a seating plan. Recalling that FIG. 3A assumes N=5, there are 2\hat{ }\hat{ }N=2\hat{ }\hat{ }5=32 possible combinations by which M_1st segments 310(1)-310(5) are coupled correspondingly to V_Net_A or V_Net_B (see FIG. 5C). That is, there are 32 seating plans for M_1st segments 310(1)-310(5) of cap cell 308(1).

For a pair of adjacent ones of M_1st segments 310(1)-310(5), where the segments of the pair are coupled correspondingly to V_Net_A and V_Net_B, a capacitance is induced between the overlap sections of the conductive segments of the pair. In some embodiments, where segments of a pair of adjacent ones of M_1st segments 310(1)-310(5) are coupled correspondingly to V_Net_A and V_Net_B, the pair is referred to as an M_1st capacitive pair (CPR) and the capacitance of the M_1st CPR is referred to as M_1st kernel capacitance, cap_krnl_1. A total capacitance of a cap cell is the product of cap_krnl_1 multiplied by the quantity of capacitive pairs in seating plan for the cap cell.

For a pair of adjacent ones of M_1st segments 310(1)-310(5), where both segments of the pair are coupled to V_Net_A or both segments of the pair are coupled to V_Net_B, substantially no capacitance is induced between the overlap sections of the conductive segments of the pair. In some embodiments, where both segments of the pair are coupled to V_Net_A or both segments of the pair are coupled to V_Net_B, the pair is referred to as an M_1st dummy pair.

For a given cap cell that has N quantity of M_1st segments and which is free from having segments in another layer, e.g., cap cell 308(1), a seating plan in which V_Net_A and V_Net_B are interleaved yields a maximum quantity of CPRs for the given cap cell. For the given cap cell, there are two seating plans that achieve the maximum quantity of CPRs, i.e., the maximum capacitance. In some embodiments, the two seating plans that achieve the maximum quantity of CPRs are referred to as a first maximum CPR (max-CPR) seating plan and a second max-CPR seating plan. The first max-CPR seating plan has odd M_1st segments coupled to V_Net_A and even M_1st segments are coupled to V_Net_B (see Row 13 of FIG. 5C). The second max-CPR seating plan is the converse of the first max-CPR seating plan. The second max-CPR seating plan has odd M_1st segments are coupled to V_Net_B and even M_1st segments are coupled to V_Net_A (see Row 26 of FIG. 5C).

For a cap cell that has N quantity of M_1st segments and which is free from having segments in another layer, the maximum quantity of CPRs, q_max, is N-1 such that q_max=(N-1). Recalling that FIG. 3A assumes that N=5, each of the two max-CPR seating plans for cap cell 308(1) achieves four CPRs. FIG. 3A also assumes the first max-CPR seating plan for cap cell 308(1) in which odd M_1st segments are coupled to V_Net_A and even M_1st segments are coupled to V_Net_B resulting in CPRs 312(1)-312(4) (see Row 13 of FIG. 5C), i.e., at total of four CPRs. More specifically, in FIG. 3A, M_1st segments 310(1), 310(3) and 310(5) are coupled to V_Net_A and M_1st segments 310(2) and 310(4) are coupled to V_Net_B. In some embodiments, cap cell 308 has the second max-CPR seating plan (see Row 26 of FIG. 5C).

In FIG. 3A: CPR 312(1) is comprised of M_1st segments 310(1) and 310(2); CPR 312(2) is comprised of M_1st segments 310(2) and 310(3); CPR 312(3) is comprised of M_1st segments 310(3) and 310(4); and CPR 312(4) is comprised of M_1st segments 310(4) and 310(5).

M_1st kernel capacitance, cap_krnl_1, is proportional to the quotient of the M_1st overlap-length divided by the M_1st separation distance. In FIG. 3A, cap_krnl_1 for cap cell 308(1) is cap_krnl_1∝D_ovrlp_1/S1. Recalling that D_ovrlp_1=L1 in FIG. 3A, cap_krnl_1 for cap cell 308(1) can be restated as cap_krnl_1∝L1/S1.

Regarding FIG. 3A, in some embodiments, a cap cell that has N quantity of M_1st segments and which is free from having segments in another layer is referred to as a single layer cap cell. Cap cell 308(1) is an example of a one-layer cap cell. In some embodiments, a one-layer cap cell is referred to as a single-layer cap cell. The capacitance of a given one-layer cap cell as a whole, 1L_cap_whol, is the same as the capacitance of the M_1st layer, cap_layr_M_1st. The capacitance of the M_1st layer is the product of cap_krnl_1 multiplied by the quantity of CPRs in the seating plan. The maximum value of cap_layer_M_1st for the given cap cell, cap_max_M_1st, is the product of cap_krnl_1 multiplied by the maximum quantity q_max of CPRs in the max-CPR seating plan. Recalling that FIG. 3A assumes N=5, q_max is N-1 such that q_max=(N-1)=4. The capacitance for cap cell 308(1), cap_308_1, equals cap_max_M_1st such that cap_308_1=cap_max_M_1st=4*cap_krnl_1 for cap cell 308(1).

Regarding FIG. 3A, recalling the 32 seating plans for a cap cell having N=5quantity of M_1st segments, e.g., cap cell 308(1), the following is to be understood: putting aside the two seating plans that achieve max-CPR, each of the remaining 30 seating plans of the N=5 type cap cell (see FIG. 5C) achieves a quantity of CPRs, q_cell, that is in a range 0≤(q_cell)≤(N-2); the remaining 30 seating plans yield a capacitance as a whole for the N=5 type cap cell that is a fraction of cap_max_M_1st; in some embodiments, the capacitance that is a fraction of cap_max_M_1st is referred to as the fractional capacitance, cap_frac; in some embodiments, the remaining 30 seating plans for the N=5 type cap cell are referred to as non-max-CPR seating plans; and the fractional capacitance cap_frac of the non-max-CPR seating plans for the N=5 type cap cell falls into a range 0≤(cap_frac)≤(N-2)*cap_krnl_1 such that cap_frac <cap_max_M_1st. In some embodiments, a cap cell having one of the two max-CPR seating plans and thus a maximum value of capacitance (max-cap) value of capacitance, e.g., cap cell 308(1), is referred to as a unit cap cell because each of the remaining 30 seating plans for the N=5 type cap cell achieve a capacitance as a whole that is a fraction of cap_max_M_1st.

Regarding FIG. 3A, in some embodiments, top and bottom boundaries of a fabricated cap cell (e.g., corresponding to cap cell 308(1)) are recognizable as follows: first ends of M_1st segments 310(1)-310(5) are substantially aligned and define a first reference line substantially parallel to, and at least proximate (if substantially collinear with) a first (e.g., top) boundary of the cap cell; and second ends of M_1st segments 310(1)-310(5) are substantially aligned and define a second reference line substantially parallel to, and at least proximate (if not substantially collinear with), a second (e.g., bottom) boundary of the cap cell. In some embodiments first ends and second ends of M_1st segments (e.g., 310(1)-310(5)) are formed as part of a cut-metal process (e.g., blocks 732-734 discussed below).

In some embodiments in which first strips (e.g., see block 736) are etched (e.g., block 738) to form the M_1st segments, replacement dielectric (RD) structures replace the cut/etched portions the first strips. In some embodiments, the RD structures are formed of a first dielectric material that is different than a second dielectric material that fills interstitial spaces. In some embodiments, the first dielectric material is the same as the second dielectric material.

Regarding FIG. 3A, in some embodiments, a context for understanding left and right boundaries of a fabricated cap cell (e.g., corresponding to cap cell 308(1)) is as follows. In an array comprised of cap cells that have N quantity of M_1st segments and which are free from having segments in another layer, e.g., cap cell 308(1), extra space in the form of a first gap is provided between adjacent first and second cap cells. More particularly, each first gap is provided between an M_1st segment in the first cap cell which is adjacent to an M_1st segment in the second cap cell (adjacent border M_1st segments representing an M_1st border pair). In a circumstance in which the M_1st segments of an M_1st border pair are coupled correspondingly to V_Net_A and V_Net_B, or vice-versa, the first gap therebetween ensures that substantially no capacitance, i.e., at most a negligible capacitance, is induced in the M_1st border pair. In FIG. 3A, examples of the first gap are illustrated, in part, using ghosts of M_1st segment (M_1st ghosts) 311(1) and 311(2). In some embodiments, each of M_1st ghosts 311(1) and 311(2) represents a dielectric structure (e.g., an instance of an RD structure, discussed above) that replaces an M_1st segment that otherwise would be present. In such an array, each first gap has a size, G1 (not shown), where G1 ≈2*S1+S2. In a circumstance similar to the adjacent first and second cap cells albeit in which the first cap cell is replaced by a first circuit, the first gap nevertheless is provided between the border M_1st segment in the second cap cell and a nearest M_1st segment in the first circuit to ensure substantially that no capacitance is induced between the border M_1st segment in the second cell and the nearest M_1st segment in the first circuit. In other words, the first gap is provided adjacent each border M_1st segment in a cap cell (e.g., 308(1)) to avoid the border M_1st segment from becoming part of an unintended capacitance pair.

Regarding FIG. 3A, in some embodiments, left and right boundaries of a fabricated cap cell (e.g., corresponding to cap cell 308(1)) are recognizable as follows: relative to the second direction (e.g., parallel to the X-axis), sets of M_1st segments (e.g., a set having M_1st segments corresponding to 310(1)-310(4)) are identified, where the M_1st segments of each set are separated by a first distance (e.g., S1); relative to the second direction (e.g., parallel to the X-axis), for each set, gaps (e.g., G1) correspondingly to the left and right of the set are identified; for each set, a first reference line is identified, where the first reference line extends in the first direction (e.g., parallel to the Y-axis), is leftward and adjacent to the leftmost M_1st segment (e.g., corresponding to 310(1)), and is proximal to the left edge of the leftmost M_1st segment but no more than a distance, D1 (not shown), from the left edge of the leftmost M_1st segment such that D1≈S1/2; for each set, a second reference line is identified, where the second reference line extends in the first direction (e.g., parallel to the Y-axis), is rightward and adjacent to the rightmost M_1st segment (e.g., corresponding to 310(5)), and is proximal to the right edge of the rightmost M_1st segment but no more than distance D1 from the right edge of the rightmost M_1st segment; each set is regarded as a fabricated cap cell (e.g., corresponding to 308(1)); the left boundary of the fabricated cap cell is regarded as being the first reference line; and the right boundary of the fabricated cap cell is regarded as being the first reference line.

In some embodiments, M_1st ghosts 311(1) and 311(2) are formed of a dielectric material (e.g., an oxide) that is different than interstitial material (not shown) which fills interstitial space around the M_1st segments, e.g., the interstitial material being another dielectric material. In some embodiments, M_1st ghosts 311(1) and 311(2) are formed of a nitride material whereas the interstitial material is an oxide, or vice versa. In some embodiments, M_1st ghosts 311(1) and 311(2) are formed of a material that is the same as the interstitial material such that M_1st ghosts 311(1) and 311(2) are more easily discerned (or identified) in the corresponding layout diagram than in the fabricated cap cell. In some embodiments, M_1st ghosts 311(1) and 311(2) are referred to as cut-M_1st (CM_1st) structures.

In some embodiments, each of M_1st ghosts 311(1)-311(2) is based on a gate segment as a precursor. In some embodiments, an M_1st ghost, e.g., 311(1)-311(2), is formed by first forming an M_1st segment, sacrificing/removing (e.g., etching) the M_1st segment to form a trench, (optionally) removing a portion of a substrate that previously had been under or over or around the M_1st segment to deepen the trench, and then filling the trench with one or more dielectric materials such that the physical dimensions of the resultant electrical isolation structure, i.e., the M_1st ghost, are similar to the dimensions of the M_1st segment which was sacrificed. In some embodiments, an M_1st ghost is a dielectric feature that includes one or more dielectric materials (e.g., oxide, nitride, oxynitride, or other suitable materials), and functions as an isolation feature.

Whereas FIG. 3A assumes the first max-CPR seating plan for N=5 type cap cell, i.e., for cap cell 308(1), an example of one of the 30 non-max-CPR seating plans for the N=5 type cap cell is shown in FIG. 3B.

In FIG. 3B, cap cell 308(2) is similar to cap cell 308(1) of FIG. 3A. For purposes of brevity, the discussion will focus on differences of cap cell 308(2) as compared to cap cell 308(1) rather than on similarities. For simplicity of illustration, cap cell 308(2) omits M_1st ghosts 311(1)-311(2) of cap cell 308(1).

In FIG. 3B, M_1st segment 310(3) is coupled to V_Net_B rather than to V_Net_A as in FIG. 3A. As a result, cap cell 308(2) has a total of two CPRs, namely 312(1) and 312(4) (see Row 12 of FIG. 5C), rather than the four CPRs as in FIG. 3A, the latter being CPRs 312(1)-312(4). The capacitance of cap cell 308(2), cap_308_2, is half the capacitance of cap cell 308(1) such that cap_308_2=(cap_308_1)/2. More generally, at half the capacitance of cap cell 308(1), the capacitance of cap cell 308(2) is an example of a non-max-cap value (non-max value) of capacitance.

In some embodiments, the seating plan of cap cell 308(2) is referred to as a half-max-CPR seating plan whereas the seating plan of cap cell 308(1) is referred to as a max-CPR seating plan. In some embodiments, cap cell 308(2) is referred to as a half cell whereas cap cell 308(1) is referred to as a unit cell. More generally, a half-max-CPR seating plan is an example of a non-max-CPR seating plan.

Cap cell 308(1) of FIG. 3A and cap cell 308(2) of FIG. 3B represent two of the 32 seating plans that are possible for the N=5 type cap cell. All 32 seating plans for the N=5 type cap cell are shown in FIG. 5C (discussed below).

In some embodiments, a cap cell in a semiconductor device based on a layout diagram (e.g., FIGS. 3A-3B) is referred to as a fabricated cap cell. According to another approach for manufacturing an array of cap cells in which each cap cell can have up to a maximum of N quantity of M_1st segments for the M_1st layer and is free from having segments in another layer, the cap cells have correspondingly different physical arrangements of the conductive segments for purposes of achieving different cell capacitances. That is, according to the other approach, the cap cells have substantially non-uniform physical arrangements. In general, resolution enhancement techniques (RETs) and/or optical proximity correction (OPC) do not change cell regions uniformly. That is, in general, RETs and/or OPC tend to make cell-region-specific changes, i.e., tend to make non-uniform changes to cell regions. Also, in general, manufacturing tolerances inevitably produce variations between the capacitances of fabricated cap cells. The non-uniformity of the cap cells according to the other approach is worsened/exaggerated in the corresponding fabricated cap cells due to (A) the non-uniform corrections introduced by RETs and/or OPC and (B) manufacturing tolerances, where the effects of (A) and/or (B) result in worsened/exaggerated variations between the capacitances of fabricated cap cells. That is, (A) and/or (B) worsen/exaggerate mismatches in the capacitances of the fabricated cap cells according to the other approach. Such mismatch reduces reliability and/or reduces performance and/or increases power consumption and/or the like of the fabricated cap cells according to the other approach. By contrast, at least some of the present embodiments produce an array of cap cells comprised of uniform M_1st-segment-count cap cells, where the uniformity lessens the variations in fabricated cap cells introduced by (i) RETs and/OPC and (ii) manufacturing tolerances, as compared to the other approach, i.e., where the uniformity reduces mismatches between the fabricated cap cells as compared to the other approach. An array of uniform M_1st-segment cap cells according to at least some of the present embodiments improve reliability and/or performance and/or power consumption and/or the like of the fabricated cap cells as compared to the other approach.

Rather than proceed next to discussing FIGS. 3C-3D, instead the discussion will jump to discussing FIG. 5C and afterward discuss FIGS. 3C-3D.

FIG. 5C is a table of seating plans for a cap cell having B=5 quantity of M-1st segments, in accordance with some embodiments.

Regarding FIG. 5C, an example of a cap cell B=5 quantity of M_1st segments is cap cell 308(1) of FIG. 3A, or the like. It is noted that the table of FIG. 5C assumes a context of the M_1st layer. In some embodiments, the context of the table of FIG. 5C is the M_2nd layer. In some embodiments, the context of the table of FIG. 5C is a metallization layer other than the M_1st layer or the M_2nd layer.

The table of FIG. 5C includes the following: a first column labeled ‘Row #’; a second column labeled ‘M_1st Segments Seating Plan’; a third column labeled ‘#CPRs’; a fourth column labeled ‘Gray Code bits, N=5’; and a fifth column labeled ‘Cell Cap Description’.

In the table of FIG. 5C, entries in the first column indicate the corresponding numbers of the rows in the table.

Regarding the second column, each entry is a sequence of bits representing a corresponding one of the 32 seating plans for the N=5 type cap cell. That is, for each entry in the second column, the positions of the bits in the sequence correspondingly represent M_1st segments 310(1)-310(5). Each bit in the sequence is a binary digit. For each bit in the sequence, the value of the bit is: zero if the corresponding one of M_1st segments 310(1)-310(5) is coupled to V_Net_A; or one if the corresponding one of M_1st segments 310(1)-310(5) is coupled to V_Net_B. For each bit in the sequence of the second column, a bit-value of zero is shown with a first fill color/pattern, and a bit value of one is shown with a different second fill color/pattern.

The third column in the table of FIG. 5C indicates the number of CPRs yielded by the corresponding seating plan in the second column.

The fourth column lists the Gray code for the corresponding seating plan. For a given row in the table of FIG. 5C, it is noted that the sequence of ones and/or zeroes in the seating plan of the second column is the same as the bit sequence of the Gray code. Row 13 of the table of FIG. 5C corresponds to cap cell 308(1) of FIG. 3A. Row 12 of the table of FIG. 5C corresponds to cap cell 308(2) of FIG. 3B.

The fifth column in the table of FIG. 5C describes the capacitance of the corresponding seating plan. Each of rows 13 and 26 of the table of FIG. 5C is a max-CPR seating plan which achieves 4 CPRs, i.e., all of the four possible CPRs are achieved (4/4). In some embodiments, again, a cap cell having a max-CPR seating plan achieves max-cap value of capacitance and is referred to as a unit cap cell. As such, the label in the fifth column for each of rows 13 and 26 is ‘unit (4/4)’.

Regarding the table of FIG. 5C, each of rows 4-5, 8-9, 12, 16, 18-19, 23, 27 and 30-31 is a half-max-CPR seating plan which achieves 2 CPRs, i.e., half of the four possible CPRs are achieved (2/4). In some embodiments, again, a cap cell having a half-max-CPR seating plan achieves half of the max-cap value of capacitance and is referred to as a half cell. As such, the label in the fifth column for each of rows 4-5, 8-9, 12, 16, 18-19, 23, 27 and 30-31 is ‘half (2/4)’. The half-max-CPR seating plan of row 12 is adjacent to the max-CPR seating plan of row 13. That is, the half-max-CPR seating plan of row 12 differs by one bit as compared to the max-CPR seating plan of row 13. The half-max-CPR seating plan of row 27 is adjacent to the max-CPR seating plan of row 26. That is, the half-max-CPR seating plan of row 27 differs by one bit as compared to the max-CPR seating plan of row 26.

Regarding the table of FIG. 5C, each of rows 1 and 22 is a seating plan that achieves no CPRs. In some embodiments, the seating plans of that achieve no CPRs are referred to as dummy seating plans and the corresponding cap cells are referred to as dummy cells. As such, the label in the fifth column for each of rows 1 and 22 is ‘dummy (0/4)’.

Regarding the table of FIG. 5C, each of rows 2-3, 6, 11, 17, 21, 24 and 32 is a seating plan which achieves 1 CPR, i.e., one of the four possible CPRs are achieved (1/4). As such, the label in the fifth column for each of rows 2-3, 6, 11, 17, 21, 24 and 32 is ‘(1/4)’. Each of rows 7, 10, 14-15, 20, 25 and 28-29 is a seating plan which achieves 3 CPRs, i.e., three of the four possible CPRs are achieved (3/4). As such, the label in the fifth column for each of rows 7, 10, 14-15, 20, 25 and 28-29 is ‘(3/4)’.

Regarding the 32 seating plans represented by the corresponding sequences of the second column of the table of FIG. 5C, the sequences are representable by different binary codes. FIG. 5C assumes the binary code to be a Gray code. In some embodiments, the binary code is the natural binary code. In some embodiments, the binary code is something other than a Gray code or the natural binary code.

The natural binary code is an example of a weighted code. With the natural binary code, incrementing or decrementing from a first state to an adjacent second changes at least one but as many as all bits depending on the number represented by the first state and the number represented by the second state. By contrast, a Gray code is an example of a non-weighted code. With a Gray code, incrementing or decrementing from a first state to an adjacent second state changes only one bit regardless of the number represented by the first state or the number represented by the second state.

In the table of FIG. 5C, for each row, the bit sequence representing the seating plan: differs from the preceding adjacent seating plan by one bit; and differs from the succeeding adjacent seating plan by one bit. For example, the half-max-CPR seating plan of row 12: differs by one bit as compared to the seating plan of row 11; and differs by one bit as compared to the max-CPR seating plan of row 13. Also, for example, the seating plan of row 32: differs by one bit as compared to the seating plan of row 31; and differs by one bit as compared to the seating plan of row 1.

In a context of an array of cap cells in which each cap cell has a maximum of N quantity of M_1st segments and is free from having segments in another layer, in some embodiments, a design guideline seeks to reduce if not minimize physical differences between adjacent instances of the cap cells (e.g., 208). Using uniform M_1st-segment-count cap cells according to at least some of the present embodiments facilitates complying with the design guideline. Furthermore, due to the demands of the routing & placement phase of IC design, it is beneficial to have multiple seating plans for the uniform M_1st-segment-count cap cells of the array. Using the Gray code-based seating plans of FIG. 5C further facilitates compliance with the design guideline.

In some embodiments, the Gray code-based seating plans of FIG. 5C facilitates physical design watermarking of a fabricated device that includes fabricated cap cells based on instances of cap cell 308(1) which are selectively varied according to the Gray code-based seating plans of FIG. 5C. In some embodiments, the physical design watermark is defined using a fabricated array (e.g., 202) of fabricated cap cells, the latter being based instances of cap cell 308(1) which are selectively varied according to the Gray code-based seating plans of FIG. 5C. In some embodiments, the physical design watermark is defined using two or more fabricated arrays (e.g., 202) of fabricated cap cells, the latter being based instances of cap cell 308(1) which are selectively varied according to the Gray code-based seating plans of FIG. 5C.

The discussion will now turn back to FIGS. 3C-3D.

More specifically, FIGS. 3C-3D are layout diagrams of corresponding cap cells 308(3)-308(4), in accordance with some embodiments.

In FIG. 3C, cap cell 308(3) is an example of one or more of cap cells 208 of FIG. 2. In FIG. 3D, cap cell 308(4) is an example of one or more of cap cells 208 of FIG. 2.

Regarding FIG. 3C, cap cell 308(3) is similar to cap cell 308(1) of FIG. 3A. For purposes of brevity, the discussion will focus on differences of cap cell 308(3) as compared to cap cell 308(1) rather than on similarities.

Not only does cap cell 308(3) include N quantity of M_1st segments in the M_1st layer as does cap cell 308(1) of FIG. 3A, but cap cell 308(3) further includes G quantity of segments in a second metallization (M_2nd) layer, the M_2nd layer being above or below the M_1st layer, and G being a positive integer. FIG. 3C assumes that G=3. In some embodiments, G<N. In some embodiments, G is a positive integer but not equal to 3. By contrast, cap cell 308(1) has a maximum of N quantity of M_1st segments and is free from having segments in another layer, e.g., the M_2nd layer.

More specifically, each of cap cells 308(3) and 308(4) includes M_2nd segments 316(1)-316(3) extending in the second direction (e.g., parallel to the X-axis) and having a pitch p_M_2nd(1).

Relative to the first direction (e.g., parallel to the Y-axis), each of M_2nd segments 316(1)-316(3) has a uniform width, i.e., substantially has a second width W2. As a result of the pitch and uniform width, adjacent ones of M_2nd segments 316(1)-316(3) are separated from each other by a unform distance, i.e., substantially by a distance S2.

Relative to the X-axis, each of M_2nd segments 316(1)-316(3) has a length L2. Cap cell 308(3) has cell boundary 314(1).

In each of cap cells 308(3) of FIGS. 3C and 308(4) of FIG. 3D, each of M_2nd segments 316(1)-316(3) has an overlap section with respect to an adjacent corresponding one of the M_2nd segments, each overlap section substantially having an overlap-length D_ovrlp_2 with respect to an adjacent corresponding one of M_2nd segments 316(1)-316(3).

In FIGS. 3C-3D, in each of M_2nd segments 316(1)-316(3), the overlap section spans substantially the entire M_2nd segment such that the overlap-length is substantially the same as the overall length, D_ovrlp_2=≈L2. In some embodiments, the overlap section spans a fraction of the length (e.g., FIGS. 3G-3H). Cap cell 308(3) has overlap boundary 315(1). Because D_ovrlp_1=≈L1 and D_ovrlp_2=≈L2, overlap boundary 315(1) is the same as cell boundary 314(1).

During manufacture, e.g., during a BEOL fabrication, each of M_2nd segments 316(1)-316(3) is selectively configured to be coupled to one or more corresponding ones of M_1st segments 310(1)-310(5) by one or more corresponding instances of a V_1st via 318. As such, each of M_2nd segments 316(1)-316(3) is selectively configured to be coupled to the first voltage V_Net_A or the second voltage V_Net_B. A first interconnection (V_1st) layer is between the M_1st layer and the M_2nd layer.

Recalling that FIG. 3C assumes G=3, there are 2\hat{ }\hat{ }G=2\hat{ }\hat{ }3=8 possible combinations by which M_2nd segments 316(1)-316(3) are coupled correspondingly to V_Net_A or V_Net_B (see FIG. 5A). That is, there are 8 seating plans for M_2nd segments 316(1)-316(3) of cap cell 308(3).

In some embodiments, where segments of a pair of adjacent ones of M_2nd segments 316(1)-316(3) are coupled correspondingly to V_Net_A and V_Net_B, the pair is referred to as a capacitive pair (CPR) and the capacitance of the M_2nd CPR is referred to as M_2nd kernel capacitance, cap_krnl_2.

A capacitance of cap cell 308(3) as a whole is the sum of the capacitance of the M_1st CPRs (discussed above) and the capacitance of the M_2nd CPRs. The capacitance of the M_2nd CPRs is the product of cap_krnl_2 multiplied by the quantity of M_2nd CPRs in the seating plan for the M_2nd segments.

For a pair of adjacent ones of M_2nd segments 316(1)-316(3), where both segments of the pair are coupled to V_Net_A or both segments of the pair are coupled to V_Net_B, substantially no capacitance is induced between the overlap sections of the conductive segments of the pair. In some embodiments, where both segments of the M_2nd pair are coupled to V_Net_A or both segments of the pair are coupled to V_Net_B, the pair is referred to as an M_2nd dummy pair.

Regarding FIG. 3C, in addition to CPRs 312(1)-312(4), cap cell 308(3) further includes CPRs 320(1) and 320(2) for a total of six CPRs. CPR 320(1) is comprised of M_2nd segments 316(1) and 316(2); and CPR 320(2) is comprised of M_2nd segments 316(2) and 316(3).

M_1st kernel capacitance cap_krnl_1 for cap cell 308(3) is the same as for cap cell 308(1). M_2nd kernel capacitance, cap_krnl_2, is proportional to the quotient of the M_2nd overlap-length divided by the M_2nd separation distance. In FIG. 3C, cap_krnl_2 for cap cell 308(3) is cap_krnl_2∝D_ovrlp_2/S2. Recalling that D_ovrlp_2=L2 in FIG. 3C, cap_krnl_2 for cap cell 308(3) can be restated as cap_krnl_2∝L2/S2.

In some embodiments, a cap cell that has N quantity of M_1st segments and G quantity of M_2nd segments is referred to as a two-layer cap cell. Cap cell 308(3) is an example of a two-layer cap cell. More generally, a cap cell that has segments in two or more layers of metallization is referred to as a multi-layer cap cell.

Cap cell 308(3) is also an example of a two-layer cap cell in which all instances of V_1st via 318 are at least substantially within cell boundary 314(1) but also within overlap boundary 315(1). In some embodiments, all instances of V_1st via 318 are at least substantially within cell boundary 314(1) though one or more instances of V_1st via 318 are substantially outside overlap boundary 315(1) (see FIGS. 3G-3H).

The capacitance of a given two-layer cap cell as a whole, 2L_cap_whol, is the sum of the capacitance of the first layer, cap_layr_M_1st, and the capacitance of the second layer, cap_layr_M_2nd. Capacitance cap_layr_M_1st is discussed above. Capacitance cap_layr_M_2nd is the product of cap_krnl_2 multiplied by the quantity of CPRs in the M_2nd seating plan.

The maximum value of cap_layer_M_2nd for the given cap cell, cap_max_M_2nd, is the product of cap_krnl_2 multiplied by the maximum quantity q_max_M_2nd of CPRs in the M_2nd max-CPR seating plan. Recalling that FIG. 3C assumes G=3, q_max_M_2nd is G−1 such that q_max_M_2nd=(G−1)=2. For cap cell 308(3) as a whole, q_max_308(3)=q_max_M_1st+q_max_M_2nd=(4+2)=6. The capacitance for cap cell 308(3) as a whole, cap_308_3, is the sum of cap_max_M_1st and cap_max_M_2nd such that cap_308_3=cap_max_M_1st+cap_max_M_2nd=4*cap_krnl_1+2*cap_krnl_2.

For a given cap cell that has N quantity of M_1st segments and G quantity of M_2nd segments, e.g., cap cell 308(3), seating plans for the M_1st layer and the M_2nd layer in which V_Net_A and V_Net_B are interleaved yields a maximum quantity of M_1st CPRs and M_2nd CPRs for the given cap cell. In terms of one-layer seating plans for cap cell 308(3): there are two M_1st max-CPR seating plans for the M_1st layer; and there are two M_2nd max-CPR seating plans for the M_2nd layer. Accordingly, in terms of two-layer seating plans for a cap cell that include M_1st segments and M_2nd segments, e.g., cap cell 308(3), there are 2\hat{ }\hat{ }2=4 max-CPR seating plans.

In terms of one-layer seating plans for a cap cell having N=5 quantity of M_1st segments and G=3 quantity of M_2nd segments, e.g., cap cell 308(3): there are 2\hat{ }\hat{ }N=2\hat{ }\hat{ }5=32 possible seating plans for the M_1st layer; and there are 2\hat{ }\hat{ }G=2\hat{ }\hat{ }3=8 possible seating plans the M_2nd layer.

In terms of two-layer seating plans for a cap cell having N=5 quantity of M_1st segments and G=3 quantity of M_2nd segments, e.g., cap cell 308(3), there are 2\hat{ }\hat{ }(N+G)=2\hat{ }\hat{ }(5+3)=256 two-layer possible seating plans.

Regarding a two-layer cap cell having N=5 quantity of M_1st segments and G=3 quantity of M_2nd segments, e.g., cap cell 308(3), the following is to be understood: putting aside the four seating plans that achieve max-CPR, each of the remaining 252 seating plans achieves a smaller quantity of CPRs than max-CPR; the remaining 252 seating plans yield a capacitance as a whole for the two-layer cap cell that is a fraction of cap_max for the two-layer cap cell, and in some embodiments, the remaining 252 seating plans for the two-layer cap cell are referred to as non-max-CPR seating plans.

In some embodiments, a two-layer cap cell having one of the four max-CPR seating plans and thus a max-cap value of capacitance, e.g., cap cell 308(3), is referred to as a two-layer unit cap cell because each of the remaining 252 seating plans for the two-layer cap cell achieve a capacitance as a whole that is a fraction of cap_max.

Whereas FIG. 3C assumes one of the four max-CPR seating plans for a two-layer cap cell having N=5 quantity of M_1st segments and G=3 quantity of M_2nd segments, i.e., for cap cell 308(3), an example of one of the 252 non-max-CPR seating plans for such a cap cell is shown in FIG. 3D.

In FIG. 3D, cap cell 308(4) is similar to cap cell 308(3) of FIG. 3C. For purposes of brevity, the discussion will focus on differences of cap cell 308(4) as compared to cap cell 308(3) rather than on similarities.

In FIG. 3D, each of M_1st segment 310(3) and M_2nd segment 316(2) is coupled to V_Net_B rather than to V_Net_A as in FIG. 3C. As a result, cap cell 308(4) has a total of three CPRs, namely, 312(1), 312(4) and 320(1) rather than the six CPRs as in FIG. 3A, the latter being CPRs 312(1)-312(4) and 320(1)-320(2). The capacitance of cap cell 308(4), cap_308_4, is half the capacitance of cap cell 308(3) such that cap_308_4=(cap_308_3)/2.

In cap cell 308(4) of FIG. 3D, the locations of the instances of V_1st via 318 are the same as the locations of the instances of V_1st via 318 in cap cell 308(3) of FIG. 3A. That is, the arrangement of the instances of V_1st via 318 in cap cell 308(4) is the same as the arrangement of the instances of V_1st via 318 in cap cell 308(3). In some embodiments, the arrangement of the instances of V_1st via 318 in cap cell 308(4) is different than the arrangement of the instances of V_1st via 318 in cap cell 308(3).

In some embodiments, the M_1st seating plan of cap cell 308(4) is referred to as an M_1st half-max-CPR seating plan whereas the M_1st seating plan of cap cell 308(3) is referred to as an M_1st max-CPR seating plan. In some embodiments, the M_2nd seating plan of cap cell 308(4) is referred to as an M_2nd half-max-CPR seating plan whereas the M_2nd seating plan of cap cell 308(3) is referred to as an M_2nd max-CPR seating plan. In some embodiments, cap cell 308(4) is referred to as a half cell whereas cap cell 308(3) is referred to as a unit cell.

In some embodiments, top and bottom boundaries of a fabricated cap cell (e.g., corresponding to cap cell 308(3)) of FIG. 3C are recognizable in a manner similar to that explained regarding cell region 308(1) of FIG. 3A. In some embodiments, left and right boundaries of a fabricated cap cell (e.g., corresponding to cap cell 308(1)) are recognizable in a manner similar to that explained regarding cell region 308(1) of FIG. 3A.

FIGS. 3E-3F are layout diagrams of corresponding cap cells 308(5)-308(6), in accordance with some embodiments.

In FIG. 3E, cap cell 308(5) is an example of one or more of cap cells 208 of FIG. 2. In FIG. 3F, cap cell 308(6) is an example of one or more of cap cells 208 of FIG. 2.

Regarding FIG. 3E, cap cell 308(3) is similar to cap cell 308(1) of FIG. 3A. For purposes of brevity, the discussion will focus on differences of cap cell 308(3) as compared to cap cell 308(1) rather than on similarities.

Not only does cap cell 308(5) include N quantity of M_1st segments in the M_1st layer as does cap cell 308(1) of FIG. 3A, but cap cell 308(5) further includes J quantity of segments in the M_2nd layer. FIG. 3E assumes that J=9. In some embodiments, N<J. In some embodiments, J is a positive integer but not equal to 9. By contrast, cap cell 308(1) has a maximum of N quantity of M_1st segments and is free from having segments in another layer, e.g., the M_2nd layer.

More specifically, each of cap cells 308(5) and 308(6) includes M_2nd segments 322(1)-322(9) extending in the first direction (e.g., parallel to the Y-axis) and having a pitch p_M_2nd(2).

Relative to the second direction (e.g., parallel to the X-axis), each of M_2nd segments 322(1)-322(9) has a uniform width, i.e., substantially has a second width W3. As a result of the pitch and uniform width, adjacent ones of M_2nd segments 322(1)-322(9) are separated from each other by a unform distance, i.e., substantially by a distance S3.

Relative to the Y-axis, each of M_2nd segments 322(1)-322(9) has a length L1. Cap cell 308(5) has cell boundary 314(1).

In each of cap cells 308(5) of FIGS. 3E and 308(6) of FIG. 3F, each of M_2nd segments 322(1)-322(9) has an overlap section with respect to an adjacent corresponding one of the M_2nd segments, each overlap section substantially having an overlap-length D_ovrlp_1 with respect to an adjacent corresponding one of M_2nd segments 322(1)-322(9).

In FIGS. 3E-3F, in each of M_2nd segments 322(1)-322(9), the overlap section spans substantially the entire M_2nd segment such that the overlap-length is substantially the same as the overall length, D_ovrlp_1=≈L1. In some embodiments, the overlap section spans a fraction of the length (e.g., FIGS. 3G-3H). Cap cell 308(5) has overlap boundary 315(1). Because D_ovrlp_1=≈L1, overlap boundary 315(1) is the same as cell boundary 314(1).

During manufacture, e.g., during a BEOL fabrication, each of M_2nd segments 322(1)-322(9) is selectively configured to be coupled to one or more corresponding ones of M_1st segments 310(1)-310(5) by one or more corresponding instances of V_1st via 318; for simplicity of illustration, instances of V_1st via 318 are not shown in FIGS. 3E-3F. As such, each of M_2nd segments 322(1)-322(9) is selectively configured to be coupled to the first voltage V_Net_A or the second voltage V_Net_B

Regarding FIG. 3E, in addition to CPRs 312(1)-312(4), cap cell 308(5) further includes CPRs 324(1)-324(8) for a total of twelve CPRs. CPR 324(1) is comprised of M_2nd segments 322(1) and 322(2); CPR 324(2) is comprised of M_2nd segments 322(2) and 322(3); CPR 324(3) is comprised of M_2nd segments 322(3) and 322(4); CPR 324(4) is comprised of M_2nd segments 322(4) and 322(5); CPR 324(5) is comprised of M_2nd segments 322(5) and 322(6); CPR 324(6) is comprised of M_2nd segments 322(6) and 322(7); CPR 324(7) is comprised of M_2nd segments 322(7) and 322(8); and CPR 324(8) is comprised of M_2nd segments 322(8) and 322(9). A capacitance of cap cell 308(5) as a whole is the sum of the capacitance of the M_1st CPRs (discussed above) and the capacitance of the M_2nd CPRs (discussed above).

For a given cap cell that has N quantity of M_1st segments and J quantity of M_2nd segments, e.g., cap cell 308(5), seating plans for the M_1st layer and the M_2nd layer in which V_Net_A and V_Net_B are interleaved yields a maximum quantity of M_1st CPRs and M_2nd CPRs for the given cap cell. In terms of one-layer seating plans for cap cell 308(5): there are two M_1st max-CPR seating plans for the M_1st layer; and there are two M_2nd max-CPR seating plans for the M_2nd layer. Accordingly, in terms of two-layer seating plans for a cap cell that include M_1st segments and M_2nd segments, e.g., cap cell 308(5), there are 2 \hat{ }\hat{ }2=4 max-CPR seating plans.

In terms of one-layer seating plans for a cap cell having N=5 quantity of M_1st segments and J=9 quantity of M_2nd segments, e.g., cap cell 308(5): there are 2\hat{ }\hat{ }N=2\hat{ }\hat{ }5=32 possible seating plans for the M_1st layer; and there are 2\hat{ }\hat{ }J=2\hat{ }\hat{ }9=512 possible seating plans the M_2nd layer.

In terms of two-layer seating plans for a cap cell having N=5 quantity of M_1st segments and J=9 quantity of M_2nd segments, e.g., cap cell 308(5), there are 2\hat{ }\hat{ }(N+J)=2\hat{ }\hat{ }(5+9)=16384 two-layer possible seating plans.

Regarding a two-layer cap cell having N=5 quantity of M_1st segments and J=9 quantity of M_2nd segments, e.g., cap cell 308(5), the following is to be understood: putting aside the four seating plans that achieve max-CPR, each of the remaining 16380 seating plans achieves a smaller quantity of CPRs than max-CPR; the remaining 16380 seating plans yield a capacitance as a whole for the two-layer cap cell that is a fraction of cap_max for the two-layer cap cell, and in some embodiments, the remaining 16380 seating plans for the two-layer cap cell are referred to as non-max-CPR seating plans.

In some embodiments, a two-layer cap cell having one of the four max-CPR seating plans and thus a max-cap value of capacitance, e.g., cap cell 308(5), is referred to as a two-layer unit cap cell because each of the remaining 16380 seating plans for the two-layer cap cell achieve a capacitance as a whole that is a fraction of cap_max.

M_1st kernel capacitance cap_krnl_1 for cap cell 308(5) is the same as for cap cell 308(1). For cap cell 308(5), M_2nd kernel capacitance, cap_krnl_3, is cap_krnl_3∝D_ovrlp_1/S3. Recalling that D_ovrlp_1=L1 in FIG. 3E, cap_krnl_3 for cap cell 308(5) can be restated as cap_krnl_3∝L1/S3.

Cap cell 308(5) is an example of a two-layer cap cell. Cap cell 308(5) is also an example of a two-layer cap cell in which all instances of V_1st via 318 (not shown) are at least substantially within cell boundary 314(1) but also within overlap boundary 315(1). In other words, where the M_1st and M_2nd layers are front side layers, each instance of V_1st via 318 (not shown) in cell 308(5) is substantially overlapped by overlap boundary 315(1). In some embodiments, each instance of V_1st via 318 (not shown) in cell 308(5) is described as being substantially covered by overlap boundary 315(1). In some embodiments in which the M_1st and M_2nd layers are backside side layers, i.e., are buried layers, such that the M-1st segments and the M_2nd segments are corresponding buried segments, each instance of V_1st via 318 (not shown) in cell 308(5) is a buried via and is substantially underlapped by overlap boundary 315(1).

In some embodiments, all instances of V_1st via 318 are at least substantially within cell boundary 314(1) though one or more instances of V_1st via 318 are substantially outside overlap boundary 315(1) (see FIGS. 3G-3H).

Recalling that FIG. 3E assumes J=9, q_max_M_2nd is J-1 such that q_max_M_2nd=(J-1)=8. For cap cell 308(5) as a whole, q_max_308(5)=q_max_M_1st+q_max_M_2nd=(4+8)=12. The capacitance for cap cell 308(5) as a whole, cap_308_5, is the sum of cap_max_M_1st and cap_max_M_2nd such that cap_308_5=cap_max_M_1st+cap_max_M_2nd=4*cap_krnl_1+8*cap_krnl_3.

Whereas FIG. 3E assumes one of the four max-CPR seating plans for a two-layer cap cell having N=5 quantity of M_1st segments and J=9 quantity of M_2nd segments, i.e., for cap cell 308(5), an example of one of the at least 16380 non-max-CPR seating plans for such a cap cell is shown in FIG. 3F.

In FIG. 3F, cap cell 308(6) is similar to cap cell 308(5) of FIG. 3E. For purposes of brevity, the discussion will focus on differences of cap cell 308(6) as compared to cap cell 308(5) rather than on similarities.

In FIG. 3F, each of M_1st segment 310(3) and M_2nd segment 322(5) is coupled to V_Net_B rather than to V_Net_A as in FIG. 3E. As a result, cap cell 308(6) has a total of six CPRs, namely, 312(1), 312(4), 324(2), 324(3), 324(6) and 324(7) rather than the twelve CPRs as in FIG. 3E, the latter being CPRs 312(1)-312(4) and 324(1)-324(8). The capacitance of cap cell 308(6), cap_308_6, is half the capacitance of cap cell 308(5) such that cap_308_6=(cap_308_5)/2.

In some embodiments, the M_1st seating plan of cap cell 308(6) is referred to as an M_1st half-max-CPR seating plan whereas the M_1st seating plan of cap cell 308(5) is referred to as an M_1st max-CPR seating plan. In some embodiments, the M_2nd seating plan of cap cell 308(6) is referred to as an M_2nd half-max-CPR seating plan whereas the M_2nd seating plan of cap cell 308(5) is referred to as an M_2nd max-CPR seating plan. In some embodiments, cap cell 308(6) is referred to as a half cell whereas cap cell 308(5) is referred to as a unit cell.

In some embodiments, top and bottom boundaries of a fabricated cap cell (e.g., corresponding to cap cell 308(5)) of FIG. 3C are recognizable in a manner similar to that explained regarding cell region 308(1) of FIG. 3A. In some embodiments, left and right boundaries of a fabricated cap cell (e.g., corresponding to cap cell 308(5)) are recognizable in a manner similar to that explained regarding cell region 308(1) of FIG. 3A.

FIGS. 3G-3H are layout diagrams of corresponding cap cells 308(7)-308(8), in accordance with some embodiments.

In FIG. 3G, cap cell 308(7) is an example of one or more of cap cells 208 of FIG. 2. In FIG. 3H, cap cell 308(8) is an example of one or more of cap cells 208 of FIG. 2. In FIG. 3G, section line 4A-4A′ corresponds to the cross-section of FIG. 4A and section line 4B-4B′ corresponds to the cross-section of FIG. 4B.

Regarding FIG. 3G, cap cell 308(7) is similar to cap cell 308(3) of FIG. 3C. For purposes of brevity, the discussion will focus on differences of cap cell 308(7) as compared to cap cell 308(3) rather than on similarities.

In FIGS. 3G-3H, each of cap cells 308(7) and 308(8) has: a cell boundary 314(2); a height L4 in the first direction (e.g., parallel to the Y-axis); and a width L6 in the second direction (e.g., parallel to the X-axis).

In FIGS. 3G-3H, in the M_1st layer, each of cap cells 308(7) and 308(8) includes M_1st segments 310(11)-310(17), M_1st ghosts 311(11)-311(12), M_2nd segments 316(11)-316(15) and M_2nd ghosts 317(11)-311(12).

More generally, each of cap cells 308(7) and 308(8) includes: K number of M_1st segments, where K is a positive integer and K≤4; and R number of M_2nd segments, where R is a positive integer and K≤4. In FIGS. 3G-3H, K is assumed to be K=7 and R is assumed to be R=5.

M_1st segments 310(11)-310(17) and M_1st ghosts 311(11)-311(12) extend parallel to the Y-axis and have a pitch p_M_1st(2). M_2nd segments 316(11)-316(15) and M_2nd ghosts 317(11)-311(12) extend parallel to the X-axis and have a pitch p_M_2nd(3). Relative to the Y-axis: each of M_1st segments 310(11)-310(17) has a length L3; and each of M_2nd segments 316(11)-316(15) has a length L5.

Relative to the X-axis, each of M_1st segments 310(11)-310(17) and M_1st ghosts 311(11)-311(12) has a uniform width, i.e., substantially has a width W4. As a result of the pitch and uniform width, adjacent ones of M_1st segments 310(11)-310(17) and M_1st ghosts 311(11)-311(12) are separated from each other by a unform distance, i.e., substantially by a distance S4.

Relative to the Y-axis, each of M_2nd segments 316(11)-316(15) and M_2nd ghosts 317(11)-311(12) has a uniform width, i.e., substantially has a width W5. As a result of the pitch and uniform width, adjacent ones of M_2nd segments 316(11)-316(15) and M_2nd ghosts 317(11)-311(12) are separated from each other by a unform distance, i.e., substantially by a distance S4.

Each of M_1st segments 310(11)-310(17) has an overlap section with respect to an adjacent corresponding one of the M_1st segments, each overlap section substantially having an overlap-length D_ovrlp_3 with respect to an adjacent corresponding one of M_1st segments 310(11)-310(17).

In FIGS. 3G-3H, in each of M_1st segments 310(11)-310(17), the overlap section spans a fraction of the M_1st segment such that the overlap-length is less than the overall length, D_ovrlp_3<L3. Relative to the M_1st layer, cap cell 308(7) has an M_1st overlap boundary 315(2). Because D_ovrlp_3<L3, overlap boundary 315(2) is different than cell boundary 314(2).

In FIGS. 3G-3H, in each of M_2nd segments 316(11)-316(15), the overlap section spans a fraction of the M_2nd segment such that the overlap-length is less than the overall length, D_ovrlp_4<L5. Relative to the M_2nd layer, cap cell 308(7) has an M_2nd overlap boundary 315(3). Because D_ovrlp_4<L5, overlap boundary 315(3) is different than cell boundary 314(2).

During manufacture, e.g., during a BEOL fabrication, each of M_1st segments 310(11)-310(17) and M_2nd segments 316(11)-316(15) is selectively configured to be coupled to voltage V_Net_A or voltage V_Net_B.

In FIG. 3G: CPR 312(1) is comprised of M_1st segments 310(12) and 310(13); CPR 312(2) is comprised of M_1st segments 310(13) and 310(14); CPR 312(3) is comprised of M_1st segments 310(14) and 310(15); CPR 312(4) is comprised of M_1st segments 310(15) and 310(16); CPR 326(1) is comprised of M_2nd segments 316(12) and 316(13); and CPR 326(2) is comprised of M_2nd segments 316(13) and 316(14). A capacitance of cap cell 308(7) as a whole is the sum of the capacitance of the M_1st CPRs (discussed above) and the capacitance of the M_2nd CPRs (discussed above).

For a given cap cell that has K quantity of M_1st segments and R quantity of M_2nd segments, e.g., cap cell 308(7), seating plans for the M_1st layer and the M_2nd layer in which V_Net_A and V_Net_B are interleaved yields a maximum quantity of M_1st CPRs and M_2nd CPRs for the given cap cell. In terms of one-layer seating plans for cap cell 308(7): there are two M_1st max-CPR seating plans for the M_1st layer; and there are two M_2nd max-CPR seating plans for the M_2nd layer. Accordingly, in terms of two-layer seating plans for a cap cell that include M_1st segments and M_2nd segments, e.g., cap cell 308(7), there are 2\hat{ }\hat{ }2=4 max-CPR seating plans.

In terms of one-layer seating plans for a cap cell having K=7 quantity of M_1st segments and R=5 quantity of M_2nd segments, e.g., cap cell 308(7): there are 2\hat{ }\hat{ }K=2\hat{ }\hat{ }7=128 possible seating plans for the M_1st layer; and there are 2\hat{ }\hat{ }R=2\hat{ }\hat{ }5=32 possible seating plans the M_2nd layer.

In terms of two-layer seating plans for a cap cell having K=7 quantity of M_1st segments and R=5 quantity of M_2nd segments, e.g., cap cell 308(7), there are 2\hat{ }\hat{ }(K+R)=2\hat{ }\hat{ }(7+5)=4096 two-layer possible seating plans.

Regarding a two-layer cap cell having K=7 quantity of M_1st segments and R=5 quantity of M_2nd segments, e.g., cap cell 308(7), the following is to be understood: putting aside the four seating plans that achieve max-CPR, each of the remaining 4092 seating plans achieves a smaller quantity of CPRs than max-CPR; the remaining 4092 seating plans yield a capacitance as a whole for the two-layer cap cell that is a fraction of cap_max for the two-layer cap cell, and in some embodiments, the remaining 4092 seating plans for the two-layer cap cell are referred to as non-max-CPR seating plans.

In some embodiments, a two-layer cap cell having one of the four max-CPR seating plans and thus a max-cap value of capacitance, e.g., cap cell 308(7), is referred to as a two-layer unit cap cell because each of the remaining 4092 seating plans for the two-layer cap cell achieve a capacitance as a whole that is a fraction of cap_max.

For cap cell 308(7), M_1st kernel capacitance, cap_krnl_4, is cap_krnl_4∝D_ovrlp_3/S4. For cap cell 308(7), M_2nd kernel capacitance, cap_krnl_5, is cap_krnl_5∝D_ovrlp_4/S5

Cap cell 308(7) is an example of a two-layer cap cell. Cap cell 308(7) is also an example of a two-layer cap cell in which all instances of V_1st via 318 are: at least substantially outside M_1st overlap boundary 315(2); and at least substantially outside M_2nd overlap boundary 315(3). In other words, each instance of V_1st via 318 (not shown) in cell 308(5) is substantially free from being overlapped by overlap boundary 315(1). In some embodiments, each instance of V_1st via 318 (not shown) in cell 308(5) is described as being substantially free from being covered by overlap boundary 315(1). The placement of instances of V_1st via 318 at least substantially outside M_1st overlap boundary 315(2) is facilitated by the inclusion of M_1st ghosts 311(11)-311(12). The placement of instances of V_1st via 318 at least substantially outside M_2nd overlap boundary 315(3) is facilitated by the inclusion of M_2nd ghosts 317(11)-317(12).

In some embodiments, all instances of V_1st via 318 are: at least substantially within M_1st overlap boundary 315(2); and at least substantially within M_2nd overlap boundary 315(3). In some embodiments, one or more instances of V_1st via 318 are at least substantially within M_1st overlap boundary 315(2) and one or more instances of V_1st via 318 are at least substantially outside M_1st overlap boundary 315(2). In some embodiments, one or more instances of V_1st via 318 are at least substantially within M_2nd overlap boundary 315(3) and one or more instances of V_1st via 318 are at least substantially outside M_2nd overlap boundary 315(3).

Recalling that FIG. 3G assumes K=7, q_max_M_1st is K-1 such that q_max_M_1st=(K-1)=6. Recalling that FIG. 3G assumes R=5, q_max_M_2nd is R-1 such that q_max_M_2nd=(R-1)=4. For cap cell 308(7) as a whole, q_max_308(7)=q_max_M_1st+q_max_M_2nd=(6+8)=14. The capacitance for cap cell 308(7) as a whole, cap_308_7, is the sum of cap_max_M_1st and cap_max_M_2nd such that cap_308_7=cap_max_M_1st+cap_max_M_2nd=6*cap_krnl_1+4*cap_krnl_3.

Whereas FIG. 3G assumes one of the four max-CPR seating plans for a two-layer cap cell having K=7 quantity of M_1st segments and R=5 quantity of M_2nd segments, i.e., for cap cell 308(7), an example of one of the at least 4092 non-max-CPR seating plans for such a cap cell is shown in FIG. 3H.

In FIG. 3H, cap cell 308(8) is similar to cap cell 308(7) of FIG. 3G. For purposes of brevity, the discussion will focus on differences of cap cell 308(8) as compared to cap cell 308(7) rather than on similarities.

In cap cell 308(8), M_1st segment 310(18) replaces M_1st segment 310(14) of cap cell 308(7). Also in cap cell 308(8), M_2nd segment 316(16) replaces M_2nd segment 316(14) of cap cell 308(7). In other words, M_1st segment 310(18) resembles a version of M_1st segment 310(14) of cap cell 308(7) that has been shifted downward within cap cell 308(8), where the difference in positions is called out by phantom boxes 328(1) and 328(2) that appear in each of FIGS. 3G-3H. Also, in other words, M_2nd segment 316(16) resembles a version of M_2nd segment 316(14) of cap cell 308(7) that has been shifted leftward within cap cell 308(8), where the difference in positions is called out by phantom boxes 330(1) and 330(2) that appear in each of FIGS. 3G-3H.

In FIG. 3H, each of M_1st segment 310(18) and M_2nd segment 316(16) is coupled to V_Net_B rather than to V_Net_A as in FIG. 3E. As a result, cap cell 308(8) has a total of three CPRs, namely, 312(11), 312(14) and 326(1) rather than the six CPRs as in FIG. 3G, the latter being CPRs 312(11)-312(14) and 326(1)-326(2). The capacitance of cap cell 308(8), cap_308_8, is half the capacitance of cap cell 308(7) such that cap_308_8=(cap_308_7)/2.

In some embodiments, the M_1st seating plan of cap cell 308(8) is referred to as an M_1st half-max-CPR seating plan whereas the M_1st seating plan of cap cell 308(7) is referred to as an M_1st max-CPR seating plan. In some embodiments, the M_2nd seating plan of cap cell 308(8) is referred to as an M_2nd half-max-CPR seating plan whereas the M_2nd seating plan of cap cell 308(7) is referred to as an M_2nd max-CPR seating plan. In some embodiments, cap cell 308(8) is referred to as a half cell whereas cap cell 308(7) is referred to as a unit cell.

Cap cell 308(8) is also an example of a two-layer cap cell in which all instances of V_1st via 318 are: at least substantially outside M_1st overlap boundary 315(2); and at least substantially outside M_2nd overlap boundary 315(3).

In cap cell 308(8) of FIG. 3H, the locations of the instances of V_1st via 318 are different than the locations of the instances of V_1st via 318 in cap cell 308(7) of FIG. 3G. The instance of V_1st via 318 that had been coupled to M_1st segment 310(14) of cap cell 308(7) has been replaced in cap cell 308(8) by an instance of V_1st via 318 that is coupled to M_1st segment 310(18). The instance of V_1st via 318 that had been coupled to M_2nd segment 316(14) of cap cell 308(7) has been replaced in cap cell 308(8) by an instance of V_1st via 318 that is coupled to M_2nd segment 316(16). In other words, the first arrangement of the instances of V_1st via 318 in cap cell 308(8) is different than the second arrangement of the instances of V_1st via 318 in cap cell 308(7). The ability to change from the first arrangement of the instances of V_1st via 318 in cap cell 308(8) to the different second arrangement of the instances of V_1st via 318 in cap cell 308(7) while keeping all instances of V_1st via 318 at least substantially outside each of M_1st overlap boundary 315(2) and M_2nd overlap boundary 315(3) is facilitated by the inclusion of M_1st ghosts 311(11)-311(12).

Despite the differences between (i) the set of M_1st segments and the set M_2nd segments in cell region 308(7) as compared to (ii) the set of M_1st segments and the set M_2nd segments in cell region 308(8), nevertheless outside M_1st overlap boundary 315(2) and outside M_2nd overlap boundary 315(3) remain the same for each of cap cell 308(7) and 308(8). That is, despite the differences between cell region 308(7) as a whole compared to cell region 308(8) as a whole, nevertheless: outside M_1st overlap boundary 315(2) remains the same for each of cap cells 308(7) and 308(8); and outside M_2nd overlap boundary 315(3) remains the same for each of cap cells 308(7) and 308(8). Furthermore, despite the differences between the set of M_1st segments and the set of M_2nd segments in cell region 308(7) as compared to the set of M_1st segments and the set of M_2nd segments in cell region 308(8), a comparison between cap cell 308(7) and cap cell 308(8) reveals the following: the area and arrangement of M_1st segment overlap remains uniform across cap cells 308(7) and 308(8); and the area and arrangement of M_2nd segment overlap remains uniform across cap cells 308(7) and 308(8). Such uniformity is facilitated by the inclusion of M_1st ghosts 311(11)-311(12).

In some embodiments, a context for understanding boundaries of a fabricated cap cell (e.g., corresponding to cap cells 308(7)-308(1)) is as follows: the leftmost M_1st segment (e.g., 310(11)) and the lowermost M_2nd segment (e.g., 316(15)) intersect to form a first L-shape corresponding to the lower left corner of the fabricated cap cell; the rightmost M_1st segment (e.g., 310(17)) and the uppermost M_2nd segment (e.g., 316(11)) intersect to form a second L-shape corresponding to the upper right corner of the fabricated cap cell, the second L-shape being rotated about 180 degrees (180°) in the X-Y plane relative to the first L-shape; between the leftmost (e.g., 310(11)) and rightmost (e.g., 310(17)) M_1st segments, there are one or more other M_1st segments (interior M_1st segments (e.g., 310(12)-310(16) and 310(18))); between the uppermost (e.g., 316(11)) and lowermost (e.g., 316(15)) M_2nd segments, there are one or more other M_2nd segments (interior M_2nd segments (e.g., 316(12)-316(14) and 316(16))); none of the interior M_1st segments (e.g., 310(12)-310(16) and 310(18)) extends substantially beyond the uppermost M_2nd segment (e.g., 316(11) nor substantially beyond the lowermost M_2nd segment (e.g., 316(15); none of the interior M_2nd segments (e.g., 316(12)-316(14) and 316(16)) extends substantially beyond the leftmost M_1st segment (e.g., 3110(11) nor substantially beyond the rightmost M_1st segment (e.g., 310(17); and the first and second L-shapes substantially define a first rectangle; and the boundary of the fabricated cap cell (e.g., 314(2)) is a second rectangle that at least substantially encloses the first rectangle.

In some embodiments, a further context for understanding the boundaries of a fabricated cap cell (e.g., corresponding to cap cells 308(7)-308(1)) is as follows: any interior M_1st segment (e.g., 310(12)-310(16) and 310(18)) which does not intersect the uppermost M_2nd segment (e.g., 316(11)) also does not substantially overlap the upper M_2nd ghost (e.g., 317(11)); any interior M_1st segment (e.g., 310(12)-310(16) and 310(18)) which does not intersect the lowermost M_2nd segment (e.g., 316(15)) also does not substantially overlap the lowermost M_2nd ghost (e. g,, 317(12)); any interior M_2nd segment (e.g., 316(12)-316(14) and 316(16)) which does not intersect the leftmost M_1st segment (e.g., 310(11)) also does not substantially overlap the leftmost M_1st ghost (e.g., 311(11)); and any interior M_2nd segment (e.g., 316(12)-316(14) and 316(16)) which does not intersect the rightmost M_1st segment (e.g., 310(17)) also does not substantially overlap the rightmost M_1st ghost (e. g, 311(12)).

In some embodiments, top and bottom boundaries of a fabricated cap cell (e.g., corresponding to cap cells 308(7)-308(8)) are recognizable as follows: a first L-shape comprised of a leftmost M_1st segment (e.g., 310(11)) and a lowermost M_2nd segment (e.g., 316(15)) is identified; a second shape comprised of a rightmost M_1st segment (e.g., 310(17)) and an uppermost M_2nd segment (e.g., 316(11)) is identified, the second L-shape being rotated about 180 degrees (180°) in the X-Y plane relative to the first L-shape; the first and second L-shapes are regarded as defining a first rectangle; interior M_1st segments (e.g., 310(12)-310(16) and 310(18)) of the first rectangle are identified; interior M_2nd segments (e.g., 316(12)-316(14) and 316(16)) of the first rectangle are identified; it is observed/confirmed that none of the interior M_1st segments (e.g., 310(12)-310(16) and 310(18)) extends substantially beyond the uppermost M_2nd segment (e.g., 316(11) nor substantially beyond the lowermost M_2nd segment (e.g., 316(15); it is observed/confirmed that none of the interior M_2nd segments (e.g., 316(12)-316(14) and 316(16)) extends substantially beyond the leftmost M_1st segment (e.g., 3110(11) nor substantially beyond the rightmost M_1st segment (e.g., 310(17); and the boundary (e.g., 314(2)) of the fabricated cap cell is regarded as a second rectangle that at least substantially encloses the first rectangle.

In some embodiments, left and right boundaries of a fabricated cap cell (e.g., corresponding to cap cells 308(7)-308(8) are recognizable in a manner similar to that explained regarding cell region 308(1) of FIG. 3A. In such embodiments, in each of FIGS. 3G-3H: an M_1st ghost 311(13) (not shown) corresponds to M_1st ghost 311(1) of FIG. 3A; and an M_1st ghost 311(14) (not shown) corresponds to M_1st ghost 311(2) of FIG. 3A.

FIGS. 4A-4B are cross-sectional diagrams of corresponding cap cells 408A and 408B of a semiconductor device 300A, in accordance with some embodiments.

In particular, each of FIGS. 4A-4B is a cross sectional view of a fabricated cap cell based on cap cell 308(7) of FIG. 3G. FIG. 4A corresponds to section line 4A-4A′ of FIG. 3G. FIG. 4B corresponds to section line 4B-4B′ of FIG. 3G.

In FIG. 4A, cap cell 408A includes: M_1st segments 410(11)-410(17); M_1st ghosts 411(11)-411(12); an instance of a V_1st via 418; and an M_2nd segment 416(13). In FIG. 4B, cap cell 408B includes: M_1st segment 410(16); an instance of a V_1st via 418; and M_2nd segments 416(11)-416(15).

FIG. 5A is a table of seating plans for a cap cell having B=3 quantity of M-1st segments, in accordance with some embodiments.

The table of FIG. 5A is similar to the table of FIG. 5C. For purposes of brevity, the discussion will focus on differences of the table of FIG. 5A as compared to the table of FIG. 5C rather than on similarities.

For a B=3 quantity of M-1st segments, there are 2\hat{ }\hat{ }B=2\hat{ }\hat{ }3=8 possible seating plans. Accordingly, there are 8 rows in the table of FIG. 5A. In other words, the table of FIG. 5A represents the 8 combinations by which the B=3 quantity of M-1st segments are coupled correspondingly to V_Net_A or V_Net_B

It is noted that the table of FIG. 5A assumes a context of the M_1st layer. In some embodiments, the context of the table of FIG. 5A is the M_2nd layer. In some embodiments, the context of the table of FIG. 5A is a metallization layer other than the M_1st layer or the M_2nd layer.

FIG. 5B is a table of seating plans for a cap cell having B=4 quantity of M-1st segments, in accordance with some embodiments.

The table of FIG. 5B is similar to the table of FIG. 5C. For purposes of brevity, the discussion will focus on differences of the table of FIG. 5B as compared to the table of FIG. 5C rather than on similarities.

For a B=4 quantity of M-1st segments, there are 2\hat{ }\hat{ }B=2\hat{ }\hat{ }4=16 possible seating plans. Accordingly, there are 16 rows in the table of FIG. 5B. In other words, the table of FIG. 5B represents the 16 combinations by which the B=4 quantity of M-1st segments are coupled correspondingly to V_Net_A or V_Net_B

It is noted that the table of FIG. 5B assumes a context of the M_1st layer. In some embodiments, the context of the table of FIG. 5B is the M_2nd layer. In some embodiments, the context of the table of FIG. 5B is a metallization layer other than the M_1st layer or the M_2nd layer.

FIG. 5D is a table of seating plans for a cap cell having B=6 quantity of M-1st segments, in accordance with some embodiments.

The table of FIG. 5D is similar to the table of FIG. 5C. For purposes of brevity, the discussion will focus on differences of the table of FIG. 5D as compared to the table of FIG. 5C rather than on similarities.

For a B=6 quantity of M-1st segments, there are 2\hat{ }\hat{ }B=2\hat{ }\hat{ }6=64 possible seating plans. Accordingly, there are 64 rows in the table of FIG. 5D. In other words, the table of FIG. 5D represents the 64 combinations by which the B=6 quantity of M-1st segments are coupled correspondingly to V_Net_A or V_Net_B

It is noted that the table of FIG. 5D assumes a context of the M_1st layer. In some embodiments, the context of the table of FIG. 5D is the M_2nd layer. In some embodiments, the context of the table of FIG. 5D is a metallization layer other than the M_1st layer or the M_2nd layer.

FIG. 5E(1)-5E(2) correspondingly are first and second parts of a table of seating plans for a cap cell having B=7 quantity of M-1st segments, in accordance with some embodiments.

The table of FIG. 5E(1)-5E(2) is similar to the table of FIG. 5C. For purposes of brevity, the discussion will focus on differences of the table of FIG. 5E(1)-5E(2) as compared to the table of FIG. 5C rather than on similarities.

For a B=7 quantity of M-1st segments, there are 2\hat{ }\hat{ }B=2\hat{ }\hat{ }7=128 possible seating plans. Accordingly, there are 128 rows in the table of FIG. 5E(1)-5E(2). In other words, the table of FIG. 5E(1)-5E(2) represents the 128 combinations by which the B=7 quantity of M-1st segments are coupled correspondingly to V_Net_A or V_Net_B

It is noted that the table of FIG. 5E(1)-5E(2) assumes a context of the M_1st layer. In some embodiments, the context of the table of FIG. 5E(1)-5E(2) is the M_2nd layer. In some embodiments, the context of the table of FIG. 5E(1)-5E(2) is a metallization layer other than the M_1st layer or the M_2nd layer.

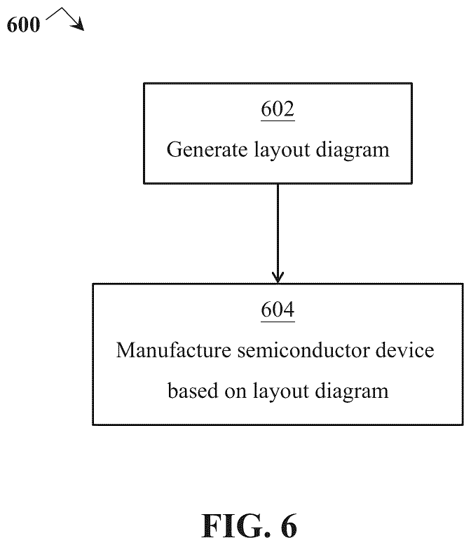

FIG. 6 is a flowchart (flow diagram) of a method 600 of manufacturing device, in accordance with some embodiments.

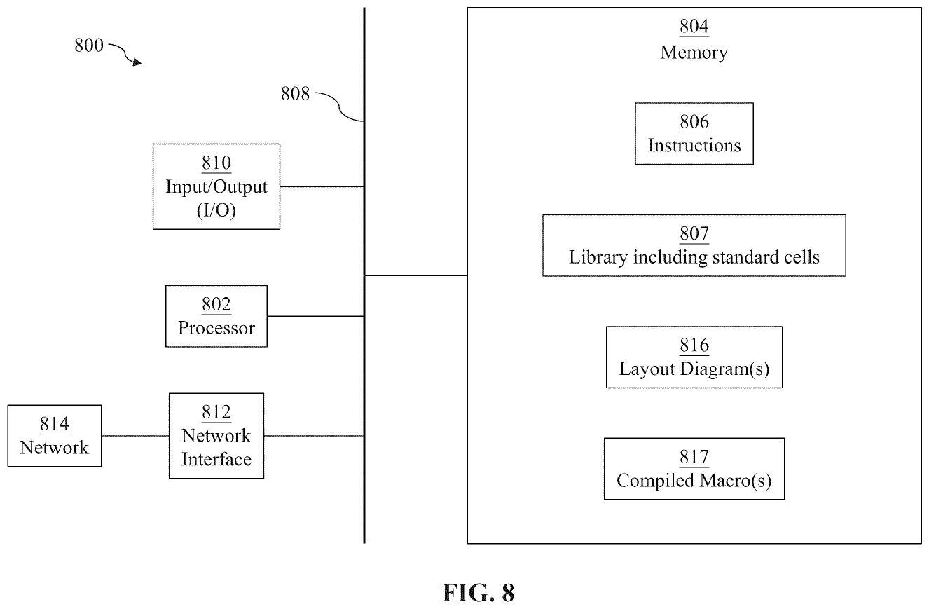

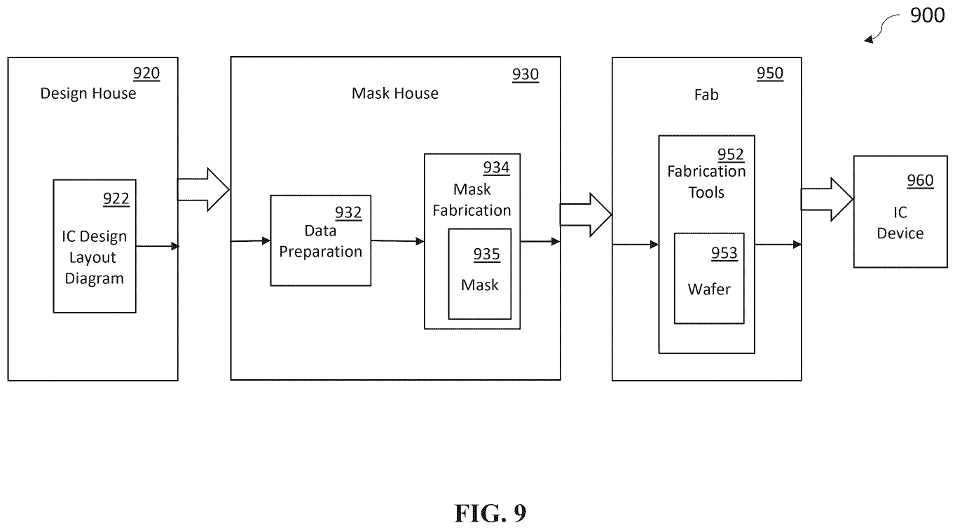

Method 600 is implementable, for example, using EDA system 800 (FIG. 8, discussed below) and an IC manufacturing system 900 (FIG. 9, discussed below), in accordance with some embodiments. Examples of semiconductor devices which can be manufactured according to method 600 include the semiconductor devices disclosed herein, or the like.

In FIG. 6, method 600 includes blocks 602-604. At block 602, a layout diagram is generated which, among other things, includes one or more layout diagrams disclosed herein, or one or more layout diagrams corresponding to one or more of the semiconductor devices disclosed herein, or the like. Block 602 is implementable, for example, using EDA system 800 (FIG. 8, discussed below), in accordance with some embodiments. From block 602, flow proceeds to block 604.

At block 604, based on the layout diagram, at least one of (A) one or more photolithographic exposures are made or (b) one or more photolithography masks are fabricated or (C) one or more components in a layer of a device, e.g., a device is fabricated. Block 604 is implementable, for example, using IC manufacturing system 900 (FIG. 9, discussed below), in accordance with some embodiments.

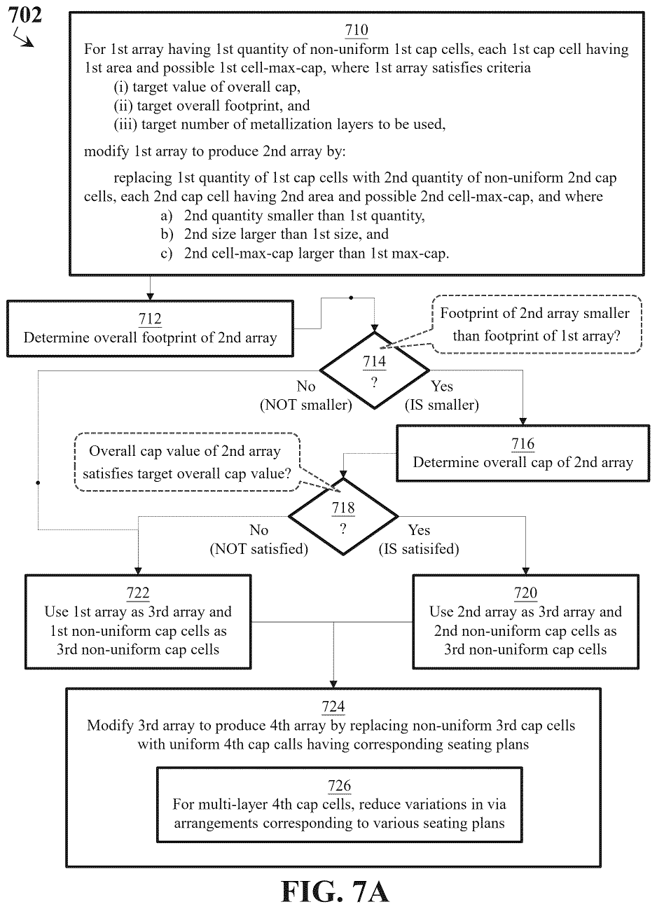

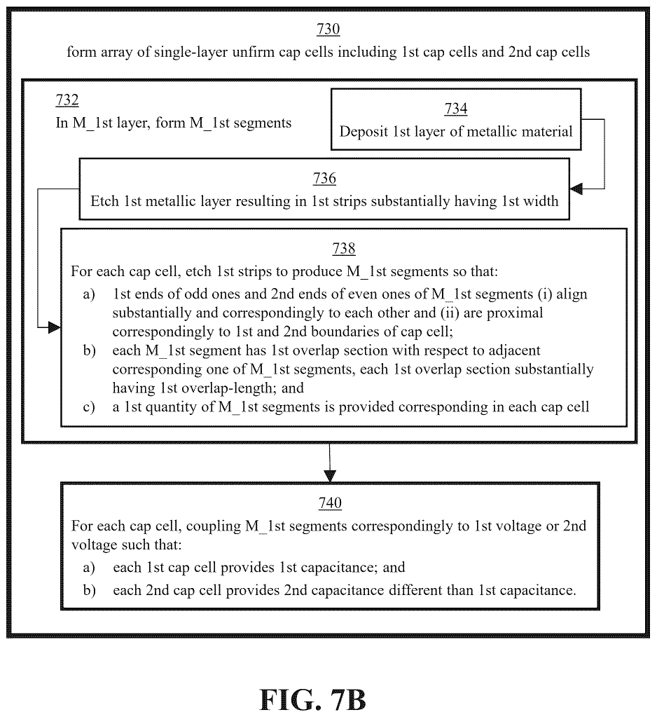

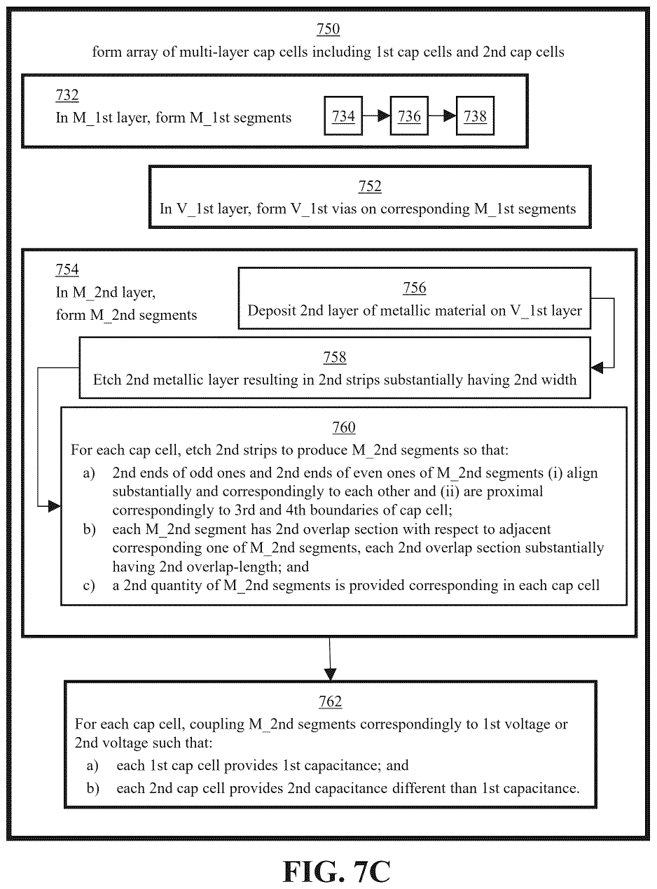

FIG. 7A is flowchart of a method 702 of generating a layout diagram, in accordance with some embodiments.

Method 702 is an example of block 602 (see FIG. 6, discussed above). A layout diagram generated by method 702, among other things, includes one or more layout diagrams disclosed herein, or one or more layout diagrams corresponding to one or more of the semiconductor devices disclosed herein, or the like.

Method 702 is implementable, for example, using EDA system 800 (FIG. 8, discussed below), in accordance with some embodiments. Method 702 includes blocks 710-726.

At block 710, a first array of a first quantity of cap cells is converted into a second array of cap cells. The conversion includes replacing the first quantity of first cap cells with a second quantity of non-uniform second cap cells, the second quantity being smaller than the first quantity. The first array satisfies criteria include: target value of overall capacitance; target overall footprint, and target number of metallization layers to be used. The first array has a first quantity of non-uniform first cap cells. Each first cap cell has: a first area; and a possible first maximum cell capacitance (max-cell-cap) depending upon whether an instance of the first cap cell is configured as a max-CRP cap cell or as a non-max-CPR cap cell. Each second cap cell has: a second area larger than first area; and a possible max-cell-cap depending upon whether an instance of the second cap cell is configured as a max-CRP cap cell or as a non-max-CPR cap cell. From block 710, flow proceeds to block 712.

At block 712, the overall footprint of the second array is determined. In some embodiments, the overall footprint of an array includes the area of each cap cell in the array and the requisite spacing between adjacent cap cells in the array. From block 712, flow proceeds to block 714.

In some embodiments, blocks 710 and 712 are described collectively as follows: for a target array of cap cells (target cap cells) that has a target array capacitance, the target unit cap cell layout diagram is designed based on a target cell-capacitance value, target overall footprint specifications, and a target number of metal layers used. In other words, in such embodiments the target array is designed as follows: in a phase (i), a first version of the given array is designed to have a first quantity of instances of the same first given unit cap cell; in a phase (ii), the first version of the given array is modified into a second version of the given array by replacing all instances of the first given unit cell (i.e., the first quantity thereof) with a second quantity of two or more versions of a second given unit cap cell; and where the second version of the given array represents the target array such that the. second quantity of the two or more versions of the second given unit cap cell represent the target cap cells. Regarding phase (i), the first version of the given array is designed to have at least: an overall array capacitance value (target overall capacitance value); each cap cell therein be an instance of the first given unit cap cell; and a layout diagram of the first given unit cap cell which is based on (a) the target overall capacitance value of the given array, (b) overall footprint specifications of (b1) the given array and/or (b2) the first given unit cell, and (c) a target number of metal layers therein. Regarding phase (ii), the second version of the given array is designed to have at least: all instances (i.e., the first quantity) of the first given unit cell be replaced with the second quantity of corresponding versions of a second given unit cap cell; the second quantity include at least (1) one or more first versions of the second given unit cap cell (e.g., a maximum capacitance version) and (2) one or more second versions of the second given unit cap cell (e.g., a half-maximum capacitance version); each second given cap cell be a larger than the first given cap cell; and the second quantity be smaller than the first quantity.

At block 714, it is decided whether the footprint of the second array is smaller than the footprint of the first array. If the outcome of the decision at block 714 is yes, then flow proceeds to block 716. If the outcome of the decision at block 714 is no, then flow proceeds to block 722.

In some embodiments, block 714 is described as follows: it is evaluated if the fractional capacitance saves area. In some embodiments, the phrase ‘fractional capacitance’ refers to the capacitance of the one or more second versions of the second given unit cap cell (e.g., a half-maximum capacitance). In some embodiments, the phrase ‘fractional capacitor mismatch’ refers to the inclusion of cap cells having ‘fractional capacitance,’ i.e., refers to the second quantity second given unit cap cells including not only the (1) at least one or more first versions of the second given unit cap cell (e.g., a maximum capacitance version) but also the (2) one or more second versions of the second given unit cap cell (e.g., a half-maximum capacitance version). In some embodiments, the phrase ‘saves area’ refers to the footprint of the second version of the given array being smaller than the footprint of the first version of the given array.

At block 716, the overall capacitance value of the second array is determined. From block 716, flow proceeds to block 718.

At block 718, it is determined if the overall capacitance value of the second array satisfies the target overall capacitance value. In some embodiments, the target overall capacitance value is a range of capacitance values such that satisfaction is achieved where the overall capacitance value of the second array falls within the range. If the outcome of the decision at block 718 is yes, then flow proceeds to block 720. If the outcome of the decision at block 718 is no, then flow proceeds to block 722.

In some embodiments, blocks 716 and 718 are described collectively as follows: it is checked whether the fractional capacitor mismatch meets/satisfies the target array capacitance.

At block 720, the second array is used as a third array and the first cap cells as third non-uniform cap cells. From block 720, flow proceeds to block 724.

At block 722, the first array is used as the third array and the second cap cells as the third non-uniform cap cells. From block 720, flow proceeds to block 724.

At block 724, the third array is modified to produce a fourth array by replacing the non-uniform third caps cells with corresponding uniform fourth cap-cells. The uniform fourth cap-cells correspondingly have variety of seating plans (see FIGS. 5A-5D, 5E(1)-5E(2), or the like). Examples of the uniform fourth cap cells include cap cells 308(1)-308(8) of corresponding FIGS. 3A-3H, or the like. Block 724 includes block 726.

In some embodiments, block 724 is described as follows: ensure the metal formation of fractional cap cells is the same as the unit capacitor; and change how signals are connected to metal segments in the fractional cells as compared to the how signals are connected to signals in the unit cells. In some embodiments, the phrase ‘ensure the metal formation of fractional cap cells is the same as the unit capacitor’ refers to replacing the non-uniform third caps cells with corresponding uniform fourth cap-cells. In some embodiments, the phrase ‘change how signals are connected to metal segments in the fractional cells as compared to the how signals are connected to signals in the unit cells’ refers to the fourth cap-cells correspondingly have variety of seating plans (see FIGS. 5A-5D, 5E(1)-5E(2), or the like).

At block 726, for multi-layer cap cells, variations in via arrangements for corresponding seating plans are reduced. Examples of multi-layer cap cells include cap cells 308(3)-308(8), or the like. An example of reducing variations in via arrangements for corresponding seating plans is provided by FIGS. 3C-3D, where the via arrangement of cap cell 308(4) of FIG. 3D is the same as the via arrangement of cap cell 308(3) of FIG. 3C. An example of reducing variations in via arrangements for corresponding seating plans is provided by FIGS. 3G-3H, where the via arrangement of cap cell 308(8) of FIG. 3H is similar to the via arrangement of cap cell 308(7) of FIG. 3G.

In some embodiments, block 726 is described as follows: if the vias are included in the formation of the capacitance area, then try to have similar via counts and via locations. In some embodiments, the phrase ‘the vias are included in the formation of the capacitance area’ refers to multi-layer cap cells. In some embodiments, the phrase ‘try to have similar via counts and via locations’ refers to reducing variations in via arrangements for corresponding seating plans.

In some embodiments, flow proceeds from block 724 to a validation block (not shown) where the third array is validated. In some embodiments, the validation block is executed using a 2D, 2.5D or a 3D validation tool, or the like. In such embodiments, if the results of the validation block are not satisfactory, then flow loops back to block 724. In some embodiments, block 724 and the validation block represent an iterative loop.

FIG. 7B is a flowchart of a method 730 of manufacturing an array of cap cells for a semiconductor device, in accordance with some embodiments.

Method 730 is an example of block 604 of FIG. 6, discussed above. Examples of an array of cap cells produced by method 730 include one or more of the arrays of cap cells disclosed herein, or the like. Method 730 is implementable, for example, using IC manufacturing system 900 (FIG. 9, discussed below), in accordance with some embodiments. Method 730 includes blocks 732-740.

The cap cells produced by method 730 are single-layer uniform cap cells including one or more first cap cells and one or more second cap cells.

At block 732, in an M_1st layer, M_1st segments are formed. An example of the M_1st layer is shown in FIGS. 4A-4B, or the like. Examples of the M_1st segments include

M_1st segments 310(1)-310(5) of FIGS. 3A-3F, M_1st segments 310(11)-310(18) correspondingly of FIGS. 3G-3H, or the like. Block 732 includes blocks 734-738. Within block 732, flow proceeds to block 734.

At block 734, a first layer of metallic material is deposited. The first layer of metallic material is a first precursor of the M_1st segments. From block 734, flow proceeds to block 736.

At block 736, the first layer of metallic is etched resulting in first strips, each of the first strips substantially having a first width. The first strips extend in a first direction (e.g., parallel to the Y-axis). The first strips are a second precursor to the M_1st segments. From block 736, flow proceeds to block 738.

At block 738, each of the first strips is etched to produce the M_1st segments that exhibit features including a first feature (discussed below), a second feature (discussed below) and a third feature (discussed below). The first feature of the M_1st segments is that first ends of odd ones and second ends of even ones of the M_1st segments (i) align substantially and correspondingly to each other and (ii) are proximal correspondingly to first and second boundaries of cap cell. The second feature of the M_1st segments is that each of the M_1st segments has a first overlap section with respect to an adjacent corresponding one of the M_1st segments, each first overlap section substantially having a first overlap-length. The third feature is that a first quantity of corresponding M_1st segments is provided in each cap cell. Regarding single-layer cap cells, examples of M_1st segments included therein that exhibit each of the first, second and third features are M_1st segments 310(1)-310(5) of cap cells 308(1)-308(5) of FIGS. 3A-3F, M_1st segments 310(11)-310(18) correspondingly of cap cells 308(7)-308(8) of FIGS. 3G-3H, or the like. From block 738, flow exits block 732 and proceeds to block 740.

At block 740, for each cap cell, M_1st segments correspondingly are coupled to a first voltage or a second voltage such that: each first cap cell provides a first capacitance and each second cap cell provides a second capacitance smaller than the first capacitance. An example of the first cap cell that provides a first capacitance is cap cell 308(1) of FIG. 3A, or the like. An example of the second cap cell that provides a second capacitance different than the first capacitance is cap cell 308(2) of FIG. 3B, or the like.

FIG. 7C is a flowchart of a method 750 of manufacturing an array of cap cells for a semiconductor device, in accordance with some embodiments.

Method 750 is an example of block 604 of FIG. 6, discussed above. Examples of an array of cap cells produced by method 750 include one or more of the arrays of cap cells disclosed herein, or the like. Method 750 is implementable, for example, using IC manufacturing system 900 (FIG. 9, discussed below), in accordance with some embodiments. Method 750 includes blocks 712-718 and 752-762.

The cap cells produced by method 750 are multi-layer, e.g., two-layer, uniform cap cells including one or more first cap cells and one or more second cap cells.

Flow begins at block 712 (discussed above). Flow proceeds within block 752 through each of blocks 714-718 (discussed above). Flow exits block 712 and proceeds to block 752.

At block 752, in a V_1st layer, V_1st vias are formed on corresponding ones of the M_1st segments. An example of the V_1st layer is shown in FIGS. 4A-4B, or the like. Examples of the Via_1st via include instances of V_1st via 318 in FIGS. 3C-3D, 3G-3H, or the like. From block 752, flow proceeds to block 754.

At block 754, in an M_2nd layer, M_2nd segments are formed. An example of the M_2nd layer is shown in FIGS. 4A-4B, or the like. Examples of the M_2nd segments include

M_2nd segments 316(1)-316(3) of FIGS. 3B-3D, M_2nd segments 322(1)-322(9) of FIGS. 3E-3F, M_2nd segments 316(11)-316(16) correspondingly of FIGS. 3G-3H, or the like. Block 754 includes blocks 756-760. Within block 754, flow proceeds to block 756.

At block 756, a second layer of metallic material is deposited. The second layer of metallic material is a first precursor of the M_2nd segments. From block 756, flow proceeds to block 758.

At block 758, the second layer of metallic is etched resulting in second strips, each of the first strips substantially having a first width. The second strips extend in a third direction (e.g., parallel to the Y-axis or to the X-axis). The second strips are a second precursor to the M_2nd segments. From block 758, flow proceeds to block 760.

At block 760, each of the second strips is etched to produce the M_2nd segments that exhibit features including a third feature (discussed below), a fourth feature (discussed below) and a fifth feature (discussed below). The fourth feature of the M_2nd segments is that first ends of odd ones and second ends of even ones of the M_2nd segments (i) align substantially and correspondingly to each other and (ii) are proximal correspondingly to third and fourth boundaries of cap cell. The fifth feature of the M_2nd segments is that each of the M_2nd segments has a second overlap section with respect to an adjacent corresponding one of the M_2nd segments, each second overlap section substantially having a second overlap-length. The sixth feature is that a second quantity of corresponding M_2nd segments is provided in each cap cell. Regarding multi-layer cap cells, e.g., two-layer cap cells, examples of M_2nd segments included therein that exhibit each of the fourth, fifth and sixth features are M_2nd segments 316(1)-316(3) of cap cells 308(3)-308(4) of FIGS. 3A-3F, M_2nd segments 322(1)-322(9) of cap cells 308(5)-308(6) of FIGS. 3E-3F, M_2nd segments 316(11)-316(16) correspondingly of cap cells 308(7)-308(8) of FIGS. 3G-3H, or the like. From block 760, flow exits block 754 and proceeds to block 762.

At block 762, for each cap cell, M_2nd segments correspondingly are coupled to a first voltage or a second voltage such that: each first cap cell provides a first capacitance and each second cap cell provides a second capacitance smaller than the first capacitance. Examples of the first cap cell that provide a first capacitance are cap cell 308(3) of FIG. 3C, cap cell 308(5) of FIG. 3E, cap cell 308(7) of FIG. 3G, or the like. An example of the second cap cell that provides a second capacitance different than the first capacitance is cap cell 308(4) of FIG. 3D, cap cell 308(6) of FIG. 3F, cap cell 308(8) of FIG. 3H, or the like.

FIG. 8 is a block diagram of an electronic design automation (EDA) system 800 in accordance with some embodiments.

In some embodiments, EDA system 800 includes an automatic placement and routing (APR) system. In some embodiments, EDA system 800 is a general purpose computing device including a processor 802 (e.g., a hardware processor) and a non-transitory, computer-readable storage medium 804. Storage medium 804, amongst other things, is encoded with, i.e., stores, computer program code 806, i.e., a set of executable instructions. Execution of instructions 806 by processor 802 represents (at least in part) an EDA tool which implements a portion of or all of one or more methods of generating layout diagrams corresponding to the layout diagrams disclosed herein, layout diagrams corresponding to the semiconductor devices disclosed herein, or the like, in accordance with one or more embodiments (hereinafter, the noted processes and/or methods).

Storage medium 804, amongst other things, stores layout diagrams 811 such as the layout diagrams disclosed herein, other the like.

Processor 802 is electrically coupled to storage medium 804 via a bus 808. Processor 802 is further electrically coupled to an I/O interface 810 by a bus 808. A network interface 812 is further electrically connected to processor 802 via bus 808. Network interface 812 is connected to a network 814, so that processor 802 and storage medium 804 are capable of connecting to external elements via network 814. Processor 802 is configured to execute computer program code 806 encoded in storage medium 804 in order to cause EDA system 800 to be usable for performing a portion of or all the noted processes and/or methods. In one or more embodiments, processor 802 is a central processing unit (CPU), a multi-processor, a distributed processing system, an application specific integrated circuit (ASIC), and/or a suitable processing unit.

In one or more embodiments, storage medium 804 is an electronic, magnetic, optical, electromagnetic, infrared, and/or a semiconductor system (or apparatus or device). For example, storage medium 804 includes a semiconductor or solid-state memory, a magnetic tape, a removable computer diskette, a random access memory (RAM), a read-only memory (ROM), a rigid magnetic disk, and/or an optical disk. In one or more embodiments using optical disks, storage medium 804 includes a compact disk-read only memory (CD-ROM), a compact disk-read/write (CD-R/W), and/or a digital video disc (DVD).

In one or more embodiments, storage medium 804 stores instructions, i.e., computer program code 806 configured to cause EDA system 800 (where such execution represents (at least in part) the EDA tool) to be usable for performing a portion of or all the noted processes and/or methods. In one or more embodiments, storage medium 804 further stores information which facilitates performing a portion of or all the noted processes and/or methods. In one or more embodiments, storage medium 804 stores library 807 of standard cells including standard cells that correspond to components of the layout diagrams disclosed herein. Storage medium 804 stores one or more layout diagrams 816 such as one or more layout diagrams corresponding to the layout diagrams disclosed herein, one or more layout diagrams corresponding to the semiconductor devices disclosed herein, one or more compiled macros 817 based on such layout diagrams, or the like.

EDA system 800 includes I/O interface 810. I/O interface 810 is coupled to external circuitry. In one or more embodiments, I/O interface 810 includes a keyboard, keypad, mouse, trackball, trackpad, touchscreen, and/or cursor direction keys for communicating information and commands to processor 802.

EDA system 800 further includes network interface 812 coupled to processor 802. Network interface 812 allows EDA system 800 to communicate with network 814, to which one or more other computer systems are connected. Network interface 812 includes wireless network interfaces such as BLUETOOTH, WIFI, WIMAX, GPRS, or WCDMA; or wired network interfaces such as ETHERNET, USB, or IEEE-1364. In one or more embodiments, a portion of or all noted processes and/or methods, is implemented in two or more EDA systems 800.

EDA system 800 is configured to receive information through I/O interface 810. The information received through I/O interface 810 includes one or more of instructions, data, design rules, libraries of standard cells, and/or other parameters for processing by processor 802. The information is transferred to processor 802 via bus 808. EDA system 800 is configured to receive information related to a user interface (UI) through I/O interface 810. The information is stored in computer-readable medium 804 as UI 842.

In some embodiments, a portion of or all the noted processes and/or methods is implemented as a standalone software application for execution by a processor. In some embodiments, a portion of or all the noted processes and/or methods is implemented as a software application that is a part of an additional software application. In some embodiments, a portion of or all the noted processes and/or methods is implemented as a plug-in to a software application. In some embodiments, at least one of the noted processes and/or methods is implemented as a software application that is a portion of an EDA tool. In some embodiments, a portion of or all the noted processes and/or methods is implemented as a software application that is used by EDA system 800. In some embodiments, a layout which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

FIG. 9 is a block diagram of an integrated circuit (IC) manufacturing system 900, and an IC manufacturing flow associated therewith, in accordance with some embodiments.

In some embodiments, based on the layout diagram generated by block 602 of FIG. 6, the IC manufacturing system 900 implements block 604 of FIG. 6 wherein at least one of (A) one or more semiconductor masks or (B) at least one component in a layer of an inchoate semiconductor integrated circuit is fabricated using manufacturing system 900. In some embodiments, the IC manufacturing system 900 implements the flowcharts of FIG. 6, or the like.

In FIG. 9, IC manufacturing system 900 includes entities, such as a design house 920, a mask house 930, and an IC manufacturer/fabricator (“fab”) 950, that interact with one another in the design, development, and manufacturing cycles and/or services related to manufacturing an IC device 960. The entities in system 900 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and supplies services to and/or receives services from one or more of the other entities. In some embodiments, two or more of design house 920, mask house 930, and IC fab 950 is owned by a single larger company. In some embodiments, two or more of design house 920, mask house 930, and IC fab 950 coexist in a common facility and use common resources.

Design house (or design team) 920 generates an IC design layout 922. IC design layout 922 includes various geometrical patterns designed for an IC device 960. The geometrical patterns correspond to patterns of metal, oxide, or semiconductor layers that make up the various components of IC device 960 to be fabricated. The various layers combine to form various IC features. For example, a portion of IC design layout 922 includes various IC features, such as an active region, gate terminal, source and drain, metal lines or vias of an interlayer interconnection, and openings for bonding pads, to be formed in a semiconductor substrate (such as a silicon wafer) and various material layers disposed on the semiconductor substrate. Source/drain region(s) may refer to a source or a drain, individually or collectively, dependent upon the context. Design house 920 implements a proper design procedure to form IC design layout 922. The design procedure includes one or more of logic design, physical design or place and route. IC design layout 922 is presented in one or more data files having information of the geometrical patterns. For example, IC design layout 922 is expressed in a GDSII file format or DFII file format.

Mask house 930 includes data preparation 932 and mask fabrication 934. Mask house 930 uses IC design layout 922 to manufacture one or more masks 935 to be used for fabricating the various layers of IC device 960 according to IC design layout 922. Mask house 930 performs mask data preparation 932, where IC design layout 922 is translated into a representative data file (“RDF”). Mask data preparation 932 supplies the RDF to mask fabrication 934. Mask fabrication 934 includes a mask writer. A mask writer converts the RDF to an image on a substrate, such as a mask (reticle) or a semiconductor wafer. The design layout is manipulated by mask data preparation 932 to comply with particular characteristics of the mask writer and/or requirements of IC fab 950. In FIG. 9, mask data preparation 932, mask fabrication 934, and mask 935 are illustrated as separate elements. In some embodiments, mask data preparation 932 and mask fabrication 934 are collectively referred to as mask data preparation.

In some embodiments, mask data preparation 932 includes optical proximity correction (OPC) which uses lithography enhancement techniques to compensate for image errors, such as those that can arise from diffraction, interference, other process effects and the like. OPC adjusts IC design layout 922. In some embodiments, mask data preparation 932 includes further resolution enhancement techniques (RET), such as off-axis illumination, sub-resolution adjust features, phase-shifting masks, other suitable techniques, and the like or combinations thereof. In some embodiments, inverse lithography technology (ILT) is further used, which treats OPC as an inverse imaging problem.

In some embodiments, mask data preparation 932 includes a mask rule checker (MRC) that checks the IC design layout that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout to compensate for limitations during mask fabrication 934, which may undo part of the modifications performed by OPC in order to meet mask creation rules.

In some embodiments, mask data preparation 932 includes lithography process checking (LPC) that simulates processing that will be implemented by IC fab 950 to fabricate IC device 960. LPC simulates this processing based on IC design layout 922 to fabricate a simulated manufactured device, such as IC device 960. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been fabricated by LPC, if the simulated device is not close enough in shape to satisfy design rules, OPC and/or MRC are repeated to further refine IC design layout 922.

The above description of mask data preparation 932 has been simplified for the purposes of clarity. In some embodiments, mask data preparation 932 includes additional features such as a logic operation (LOP) to modify the IC design layout according to manufacturing rules. Additionally, the processes applied to IC design layout 922 during data preparation 932 may be executed in a variety of different orders.

After mask data preparation 932 and during mask fabrication 934, a mask 935 or a group of masks 935 are fabricated based on the modified IC design layout. In some embodiments, an electron-beam (e-beam) or a mechanism of multiple e-beams is used to form a pattern on a mask (photomask or reticle) based on the modified IC design layout. The masks are formed in various technologies. In some embodiments, the mask is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask includes a transparent substrate (e.g., fused quartz) and an opaque material (e.g., chromium) coated in the opaque regions of the mask. In another example, the mask is formed using a phase shift technology. In the phase shift mask (PSM), various features in the pattern formed on the mask are configured to have proper phase difference to enhance the resolution and imaging quality. In various examples, the phase shift mask is an attenuated PSM or alternating PSM. The mask(s) generated by mask fabrication 934 is used in a variety of processes. For example, such a mask(s) is used in an ion implantation process to form various doped regions in the semiconductor wafer, in an etching process to form various etching regions in the semiconductor wafer, and/or in other suitable processes.

IC fab 950 is an IC fabrication business that includes one or more manufacturing facilities for the fabrication of a variety of different IC products. In some embodiments, IC fab 950 is a semiconductor foundry. For example, there may be a manufacturing facility for the front end fabrication of a plurality of IC products (front-end-of-line (FEOL) fabrication), while a second manufacturing facility may supply the back end fabrication for the interconnection and packaging of the IC products (back-end-of-line (BEOL) fabrication), and a third manufacturing facility may supply other services for the foundry business.

IC fab 950 uses mask (or masks) 935 fabricated by mask house 930 to fabricate IC device 960 using fabrication tools 952. Thus, IC fab 950 at least indirectly uses IC design layout 922 to fabricate IC device 960. In some embodiments, a semiconductor wafer 953 is fabricated by IC fab 950 using mask (or masks) 935 to form IC device 960. Semiconductor wafer 953 includes a silicon substrate or other proper substrate having material layers formed thereon. Semiconductor wafer further includes one or more of various doped regions, dielectric features, multilevel interconnects, and the like (formed at subsequent manufacturing steps).

In some embodiments, a semiconductor device includes: in a first metallization (M_1st) layer, M_1st segments extending in a first direction and having a first pitch, wherein, relative to a second direction perpendicular the first direction, each of the M_1st segments substantially having a first width and a substantially uniform first gap therebetween; and capacitor cell regions (cap cells) arranged in an array and including one or more first cap cells and one or more second cap cells, wherein each cap cell having a first quantity, and a substantially uniform physical arrangement, of corresponding ones of the M_1st segments; and wherein, for each of the cap cells, couplings between the M_1st segments and correspondingly a first voltage or a second voltage being arranged such that: each of the first cap cells providing substantially a first capacitance; and each of the second cap cells providing substantially a non-zero second capacitance smaller than the first capacitance; wherein electrical arrangements of the M_1st segments being different for the second cap cells than for the first cap cells; and wherein, for each of the cap cells: first ends of odd ones and second ends of even ones of the M_1st segments aligning substantially and correspondingly to each other and being proximal correspondingly to opposite first and second boundaries of the cap cell; and relative to the second direction, opposite third and fourth boundaries of the cap cell being in corresponding external second and third gaps proximal to corresponding outermost ones of the M_1st segments; each of the second and third gaps being larger than the first gap.

In some embodiments, the first quantity of corresponding ones of the M_1st segments in each cap cell is N; each cap cell has a maximum of N-1 capacitive pairings; in each cap cell, a capacitive pairing being a circumstance in which adjacent first and second ones of the M_1st segments are coupled correspondingly to different ones of the first or second voltages such that each capacitive pairing provides a third capacitance smaller than or equal to the second capacitance, for each of the cap cells, from a first side to a second side relative to the second direction, arrangement of the couplings between the M_1st segments and correspondingly the first voltage or the second voltage defines a binary code in which the first voltage represents a logical value of one and the second voltage represents a logical value of zero; each of two alpha values of the binary code correspond to the first capacitance; and N is a positive negative integer.

In some embodiments, each of two or more beta values of the binary code correspond to the second capacitance.

In some embodiments, the second capacitance is substantially half of the first capacitance; the binary code is a Gray code; for each of the two alpha values of the binary code, a corresponding one of the two or more beta values of the binary code differs by one bit as compared to the alpha value.

In some embodiments, the cap cells further include one or more dummy cap cells; in each dummy cap cell, each of the M_1st segments is coupled to the first voltage or each of the M_1st segments is coupled to the second voltage; each of two gamma values of the binary code correspond to the one or more dummy cap cells.

In some embodiments, in a second metallization (M_2nd) layer, M_2nd segments extending in a third direction and having a second pitch; relative to a fourth direction perpendicular the third direction, each of the M_2nd segments substantially having a second width and a substantially uniform fourth gap therebetween; and wherein: for each of the cap cells, each of the M_2nd segments is coupled correspondingly to the first voltage or the second voltage; and each cap cell has a second quantity, and a substantially uniform physical arrangement, of corresponding ones of the M_2nd segments.

In some embodiments, the third direction is parallel to the first direction; the fourth direction is parallel to the second direction, the second pitch is smaller than the first pitch; and the second width is smaller than the first width.

In some embodiments, the third direction is parallel to the second direction; the fourth direction is parallel to the first direction, the second pitch is greater than the first pitch; and the second width is greater than the first width.

In some embodiments, the semiconductor device further includes: in a first interconnection (V_1st) layer between the M_1st layer and the M_2nd layer, V_1st vias coupled to corresponding ones of the M_1st segments and corresponding ones of the M_2nd segments; and wherein: relative to the first, second, third and fourth directions: each of the first cap cells has a first arrangement of corresponding ones of V_1st vias (first via arrangement); and each of the second cap cells has a second arrangement of corresponding ones of V_1st vias (second via arrangement); and the first via arrangement is different than the second via arrangement.

In some embodiments, in each of the first cap cells, according to the first via arrangement: the V_1st vias are substantially covered by the first overlap sections of the corresponding M_1st segments and are substantially covered by the second overlap sections of the corresponding M_1st segments; and in each of the second cap cells, according to the second via arrangement: the V_1st vias are substantially covered by the first overlap sections of the corresponding M_1st segments and are substantially covered by the second overlap sections of the corresponding M_1st segments; and

In some embodiments, in each of the first cap cells, according to the first via arrangement: the V_1st vias are substantially free from being covered by the first overlap sections of the corresponding M_1st segments and are substantially free from being covered by the second overlap sections of the corresponding M_1st segments; and in each of the second cap cells, according to the second via arrangement: the V_1st vias are substantially free from being covered by the first overlap sections of the corresponding M_1st segments and are substantially free from being covered by the second overlap sections of the corresponding M_1st segments.

In some embodiments, a method (of manufacturing a semiconductor device) includes: forming an array of capacitor cell regions (cap cells), the cap cells including one or more first cap cells and one or more second cap cells; and the forming an array of cap cell regions including: in a first metallization (M_1st) layer, forming M_1st segments including: depositing a first layer of metallic first material as a precursor to the M_1st segments; etching the first layer resulting in: first strips of the first material extending in a first direction and having a first pitch relative to a perpendicular second direction; and each of the first strips substantially having a first width and a substantially uniform first gap therebetween relative to the first direction; for each cap cell, etching the first strips to produce the M_1st segments so that: each cap cell having a first quantity, and a substantially uniform physical arrangement, of corresponding ones of the M_1st segments; relative to the second direction, outermost ones of the M_1st segments being adjacent to corresponding external second and third gaps, each of the second and third gaps being larger than the first gap, and opposite first and second boundaries of the cap cell correspondingly being in the third and fourth gaps; and relative to the first direction, opposing third and fourth boundaries of each cell being proximal correspondingly to (i) substantially aligned first ends of one or more of the M_1st segments and (i) substantially aligned second ends of one or more of the M_1st segments; and for each of the cap cells, coupling the M_1st segments correspondingly to a first voltage or a second voltage such that: each of the first cap cells providing a first capacitance; and each of the second cap cells providing substantially a non-zero second capacitance different than the first capacitance; and electrical arrangements of the M_1st segments being different for the second cap cells than for the first cap cells.

In some embodiments, the forming an array of cap cell regions further includes: in a second metallization (M_2nd) layer, forming M_2nd segments including: depositing a second layer of metallic second material as a precursor to the M_2nd segments; etching the second layer resulting in: second strips of the second material extending in a third direction and having a second pitch relative to a perpendicular fourth direction; and each of the second strips substantially having a second width and a substantially uniform fourth gap relative to the third direction; for each cap cell, etching the second strips to produce the M_2nd segments so that: each cap cell having a second quantity, and a substantially uniform physical arrangement, of corresponding ones of the M_2nd segments; for each of the cap cells, coupling the M_2nd segments correspondingly to the first voltage or the second voltage.

In some embodiments, the third direction is parallel to the first direction; the fourth direction is parallel to the second direction, the second pitch is smaller than the first pitch; and the second width is smaller than the first width.

In some embodiments, the third direction is parallel to the second direction; the fourth direction is parallel to the first direction, the second pitch is greater than the first pitch; and the second width is greater than the first width.

In some embodiments, the forming an array of cap cell regions further includes: in a first interconnection (V_1st) layer over the M_1st layer, forming V_1st vias on and electrically coupled to corresponding ones of the M_1st segments; the M_2nd layer, is over the V_1st layer; the etching the second layer further resulting in: the second strips being on and coupled to corresponding ones of the M_2nd segments; and relative to the first, second, third and fourth directions, the forming V_1st vias resulting in: each of the first cap cells having a first arrangement of corresponding ones of V_1st vias (first via arrangement); and each of the second cap cells having a second arrangement of corresponding ones of V_1st vias (second via arrangement); and the first via arrangement being different than the second via arrangement.

In some embodiments, the forming V_1st vias further resulting in: in each of the first cap cells, according to the first via arrangement, the V_1st vias being substantially covered by the first overlap sections of the corresponding M_1st segments and being substantially covered by the second overlap sections of the corresponding M_1st segments; and in each of the second cap cells, according to the second via arrangement, the V_1st vias being substantially covered by the first overlap sections of the corresponding M_1st segments and being substantially covered by the second overlap sections of the corresponding M_1st segments;

In some embodiments, the forming V_1st vias further resulting in: in each of the first cap cells, according to the first via arrangement, the V_1st vias being substantially free from being covered by the first overlap sections of the corresponding M_1st segments and being substantially free from being covered by the second overlap sections of the corresponding M_1st segments; and in each of the second cap cells, according to the second via arrangement, the V_1st vias being substantially free from being covered by the first overlap sections of the corresponding M_1st segments and being substantially free from being covered by the second overlap sections of the corresponding M_1st segments.

In some embodiments, a semiconductor device includes: in a first metallization (M_1st) layer, M_1st segments extending in a first direction and having a first pitch, wherein, relative to a second direction perpendicular the first direction, each of the M_1st segments substantially having a first width and a substantially uniform first gap therebetween; in a second metallization (M_2nd) layer, M_2nd segments extending in a third direction and having a second pitch, wherein, relative to a fourth direction perpendicular the third direction, each of the M_2nd segments substantially having a second width; and capacitor cell regions (cap cells) arranged in an array and including one or more first cap cells and one or more second cap cells, wherein each cap cell having (i) a first quantity, and a substantially uniform physical arrangement, of corresponding ones of the M_1st segments and (ii) a second quantity of corresponding ones of the M_2nd segments; and wherein, for each of the cap cells, couplings (A) between the M_1st segments and correspondingly a first voltage or a second voltage and (B) between the M_2nd segments and correspondingly the first voltage or the second voltage being arranged such that: each of the first cap cells providing substantially a first capacitance; and each of the second cap cells providing substantially a non-zero second capacitance different than the first capacitance; wherein electrical arrangements of the M_1st segments being different for the second cap cells than for the first cap cells; and wherein, for each of the cap cells: first ends of odd ones and second ends of even ones of the M_1st segments aligning substantially and correspondingly to each other and being proximal correspondingly to opposite first and second boundaries of the cap cell; and relative to the second direction, opposite third and fourth boundaries of the cap cell being in corresponding external second and third gaps proximal to corresponding outermost ones of the M_1st segments; each of the second and third gaps being larger than the first gap.

In some embodiments, the semiconductor device further includes: in a first interconnection (V_1st) layer between the M_1st layer and the M_2nd layer, V_1st vias coupled to corresponding ones of the M_1st segments and corresponding ones of the M_2nd segments; and wherein: relative to the first, second, third and fourth directions: each of the first cap cells has a first arrangement of corresponding ones of V_1st vias (first via arrangement); and each of the second cap cells has a second arrangement of corresponding ones of V_1st vias (second via arrangement); and the first via arrangement is different than the second via arrangement.

It will be readily seen by one of ordinary skill in the art that one or more of the disclosed embodiments fulfill one or more of the advantages set forth above. After reading the foregoing specification, one of ordinary skill will be able to affect various changes, substitutions of equivalents and various other embodiments as broadly disclosed herein. It is therefore intended that the protection granted hereon be limited only by the definition contained in the appended claims and equivalents thereof.

What is claimed is:

1. A semiconductor device comprising:
in a first metallization (M_1st) layer, M_1st segments extending in a first direction and having a first pitch, wherein, relative to a second direction perpendicular to the first direction, each of the M_1st segments substantially having a first width and a substantially uniform first gap therebetween; and
capacitor cell regions (cap cells) arranged in an array and including one or more first cap cells and one or more second cap cells, wherein each cap cell having a first quantity, and a substantially uniform physical arrangement, of corresponding ones of the M_1st segments; and
wherein, for each of the cap cells, couplings between the M_1st segments and correspondingly a first voltage or a second voltage being arranged such that:
each of the first cap cells providing substantially a first capacitance; and
each of the second cap cells providing substantially a non-zero second capacitance smaller than the first capacitance;
wherein electrical arrangements of the M_1st segments being different for the second cap cells than for the first cap cells; and
wherein, for each of the cap cells:
first ends of odd ones and second ends of even ones of the M_1st segments aligning substantially and correspondingly to each other and being proximal correspondingly to opposite first and second boundaries of the cap cell; and
relative to the second direction, opposite third and fourth boundaries of the cap cell being in corresponding external second and third gaps proximal to corresponding outermost ones of the M_1st segments; each of the second and third gaps being larger than the first gap.

2. The semiconductor device of claim 1, wherein:
the first quantity of corresponding ones of the M_1st segments in each cap cell is N;
each cap cell has a maximum of N-1 capacitive pairings;
in each cap cell, a capacitive pairing being a circumstance in which adjacent first and second ones of the M_1st segments are coupled correspondingly to different ones of the first or second voltages such that each capacitive pairing provides a third capacitance smaller than or equal to the second capacitance,
for each of the cap cells,
from a first side to a second side relative to the second direction,
arrangement of the couplings between the M_1st segments and correspondingly the first voltage or the second voltage defines a binary code in which the first voltage represents a logical value of one and the second voltage represents a logical value of zero;
each of two alpha values of the binary code correspond to the first capacitance; and
N is a positive negative integer.

3. The semiconductor device of claim 2, wherein:
each of two or more beta values of the binary code correspond to the second capacitance.

4. The semiconductor device of claim 3, wherein:
the second capacitance is substantially half of the first capacitance;
the binary code is a Gray code;
for each of the two alpha values of the binary code,
a corresponding one of the two or more beta values of the binary code differs by one bit as compared to the alpha value.

5. The semiconductor device of claim 2, wherein:
the cap cells further include one or more dummy cap cells;
in each dummy cap cell, each of the M_1st segments is coupled to the first voltage or each of the M_1st segments is coupled to the second voltage;
each of two gamma values of the binary code correspond to the one or more dummy cap cells.

6. The semiconductor device of claim 1, further comprising:
in a second metallization (M_2nd) layer, M_2nd segments extending in a third direction and having a second pitch, wherein, relative to a fourth direction perpendicular to the third direction, each of the M_2nd segments substantially having a second width and a substantially uniform fourth gap therebetween; and
wherein:
for each of the cap cells, each of the M_2nd segments is coupled correspondingly to the first voltage or the second voltage; and
each cap cell has a second quantity, and a substantially uniform physical arrangement, of corresponding ones of the M_2nd segments.

7. The semiconductor device of claim 6, wherein:
the third direction is parallel to the first direction;
the fourth direction is parallel to the second direction,
the second pitch is smaller than the first pitch; and
the second width is smaller than the first width.

8. The semiconductor device of claim 6, wherein:
the third direction is parallel to the second direction;
the fourth direction is parallel to the first direction,
the second pitch is greater than the first pitch; and
the second width is greater than the first width.

9. The semiconductor device of claim 6, further comprising:
in a first interconnection (V_1st) layer between the M_1st layer and the M_2nd layer, V_1st vias coupled to corresponding ones of the M_1st segments and corresponding ones of the M_2nd segments; and
wherein:
relative to the first, second, third and fourth directions:
each of the first cap cells has a first arrangement of corresponding ones of V_1st vias (first via arrangement); and
each of the second cap cells has a second arrangement of corresponding ones of V_1st vias (second via arrangement); and
the first via arrangement is different than the second via arrangement.

10. The semiconductor device of claim 9, wherein:
in each of the first cap cells, according to the first via arrangement:
the V_1st vias are substantially covered by the first overlap sections of the corresponding M_1st segments and are substantially covered by the second overlap sections of the corresponding M_1st segments; and
in each of the second cap cells, according to the second via arrangement:
the V_1st vias are substantially covered by the first overlap sections of the corresponding M_1st segments and are substantially covered by the second overlap sections of the corresponding M_1st segments.

11. The semiconductor device of claim 9, wherein:
in each of the first cap cells, according to the first via arrangement:
the V_1st vias are substantially free from being covered by the first overlap sections of the corresponding M_1st segments and are substantially free from being covered by the second overlap sections of the corresponding M_1st segments; and
in each of the second cap cells, according to the second via arrangement:
the V_1st vias are substantially free from being covered by the first overlap sections of the corresponding M_1st segments and are substantially free from being covered by the second overlap sections of the corresponding M_1st segments.

12. A method of manufacturing a semiconductor device, the method comprising:
forming an array of capacitor cell regions (cap cells), the cap cells including one or more first cap cells and one or more second cap cells; and
the forming an array of cap cell regions including:
in a first metallization (M_1st) layer, forming M_1st segments including:
depositing a first layer of metallic first material as a precursor to the M_1st segments;
etching the first layer resulting in:
first strips of the first material extending in a first direction and having a first pitch relative to a perpendicular second direction; and
each of the first strips substantially having a first width and a substantially uniform first gap therebetween relative to the first direction;
for each cap cell, etching the first strips to produce the M_1st segments so that:
each cap cell having a first quantity, and a substantially uniform physical arrangement, of corresponding ones of the M_1st segments;
relative to the second direction, outermost ones of the M_1st segments being adjacent to corresponding external second and third gaps, each of the second and third gaps being larger than the first gap, and opposite first and second boundaries of the cap cell correspondingly being in the third and fourth gaps; and
relative to the first direction, opposing third and fourth boundaries of each cell being proximal correspondingly to (i) substantially aligned first ends of one or more of the M_1st segments and (i) substantially aligned second ends of one or more of the M_1st segments; and
for each of the cap cells, coupling the M_1st segments correspondingly to a first voltage or a second voltage such that:
each of the first cap cells providing substantially a first capacitance;
each of the second cap cells providing substantially a non-zero second capacitance different than the first capacitance; and
electrical arrangements of the M_1st segments being different for the second cap cells than for the first cap cells.

13. The method of claim 12, wherein:
the forming an array of cap cell regions further includes:
in a second metallization (M_2nd) layer, forming M_2nd segments including:
depositing a second layer of metallic second material as a precursor to the M_2nd segments;
etching the second layer resulting in:
second strips of the second material extending in a third direction and having a second pitch relative to a perpendicular fourth direction; and
each of the second strips substantially having a second width and a substantially uniform fourth gap relative to the third direction;
for each cap cell, etching the second strips to produce the M_2nd segments so that:
each cap cell having a second quantity, and a substantially uniform physical arrangement, of corresponding ones of the M_2nd segments; and
for each of the cap cells, coupling the M_2nd segments correspondingly to the first voltage or the second voltage.

14. The method of claim 13, wherein:
the third direction is parallel to the first direction;
the fourth direction is parallel to the second direction,
the second pitch is smaller than the first pitch; and
the second width is smaller than the first width.

15. The method of claim 13, wherein:
the third direction is parallel to the second direction;
the fourth direction is parallel to the first direction,
the second pitch is greater than the first pitch; and
the second width is greater than the first width.

16. The method of claim 13, wherein:
the forming an array of cap cell regions further includes:
in a first interconnection (V_1st) layer over the M_1st layer, forming V_1st vias on and electrically coupled to corresponding ones of the M_1st segments;
the M_2nd layer, is over the V_1st layer;
the etching the second layer further resulting in:
the second strips being on and coupled to corresponding ones of the M_2nd segments; and
relative to the first, second, third and fourth directions, the forming V_1st vias resulting in:
each of the first cap cells having a first arrangement of corresponding ones of V_1st vias (first via arrangement); and
each of the second cap cells having a second arrangement of corresponding ones of V_1st vias (second via arrangement); and
the first via arrangement being different than the second via arrangement.

17. The method of claim 16, wherein:
the forming V_1st vias further resulting in:
in each of the first cap cells, according to the first via arrangement, the V_1st vias being substantially covered by the first overlap sections of the corresponding M_1st segments and being substantially covered by the second overlap sections of the corresponding M_1st segments; and
in each of the second cap cells, according to the second via arrangement, the V_1st vias being substantially covered by the first overlap sections of the corresponding M_1st segments and being substantially covered by the second overlap sections of the corresponding M_1st segments.

18. The method of claim 16, wherein:
the forming V_1st vias further resulting in:
in each of the first cap cells, according to the first via arrangement, the V_1st vias being substantially free from being covered by the first overlap sections of the corresponding M_1st segments and being substantially free from being covered by the second overlap sections of the corresponding M_1st segments; and
in each of the second cap cells, according to the second via arrangement, the V_1st vias being substantially free from covered by the first overlap sections of the corresponding M_1st segments and being substantially free from being covered by the second overlap sections of the corresponding M_1st segments.

19. A semiconductor device comprising:
in a first metallization (M_1st) layer, M_1st segments extending in a first direction and having a first pitch, wherein relative to a second direction perpendicular to the first direction, each of the M_1st segments substantially having a first width and a substantially uniform first gap therebetween,
in a second metallization (M_2nd) layer, M_2nd segments extending in a third direction and having a second pitch, wherein, relative to a fourth direction perpendicular to the third direction, each of the M_2nd segments substantially having a second width; and
capacitor cell regions (cap cells) arranged in an array and including one or more first cap cells and one or more second cap cells, wherein each cap cell having (i) a first quantity, and a substantially uniform physical arrangement, of corresponding ones of the M_1st segments and (ii) a second quantity of corresponding ones of the M_2nd segments; and
wherein, for each of the cap cells, couplings (A) between the M_1st segments and correspondingly a first voltage or a second voltage and (B) between the M_2nd segments and correspondingly the first voltage or the second voltage being arranged such that:
each of the first cap cells providing substantially a first capacitance; and
each of the second cap cells providing substantially a non-zero second capacitance different than the first capacitance;
wherein electrical arrangements of the M_1st segments being different for the second cap cells than for the first cap cells; and
wherein, for each of the cap cells:
first ends of odd ones and second ends of even ones of the M_1st segments aligning substantially and correspondingly to each other and being proximal correspondingly to opposite first and second boundaries of the cap cell; and
relative to the second direction, opposite third and fourth boundaries of the cap cell being in corresponding external second and third gaps proximal to corresponding outermost ones of the M_1st segments; each of the second and third gaps being larger than the first gap.

20. The semiconductor device of claim 19, further comprising:
in a first interconnection (V_1st) layer between the M_1st layer and the M_2nd layer, V_1st vias coupled to corresponding ones of the M_1st segments and corresponding ones of the M_2nd segments; and
wherein:
relative to the first, second, third and fourth directions:
each of the first cap cells has a first arrangement of corresponding ones of V_1st vias (first via arrangement); and
each of the second cap cells has a second arrangement of corresponding ones of V_1st vias (second via arrangement); and
the first via arrangement is different than the second via arrangement.
